(19) United States
(12) Patent Application Publication
(10) Pub. No.: US 2020/0058802 A1
(43) Pub. Date: Feb. 20, 2020

(54) MAGNETORESISTANCE EFFECT DEVICE

(71) Applicant: TDK CORPORATION, Tokyo (JP)

(72) Inventors: Kuniyasu ITO, Tokyo (JP); Shinji HARA, Tokyo (JP)

(73) Assignee: TDK CORPORATION, Tokyo (JP)

(21) Appl. No.: 16/485,850

(22) PCT Filed: Feb. 21, 2018
(86) PCT No.: PCT/JP2018/006131

§ 371 Date: Aug. 14, 2019

(30) Foreign Application Priority Data
Mar. 3, 2017 (JP) 2017-040650

(51) Int. Cl. H01L 29/82; H01L 43/08; H01F 10/32

(52) U.S. Cl. CPC H01L 29/82; H01F 10/324; H01L 43/08

(57) ABSTRACT

A magnetoresistance effect device includes a magnetoresistance effect element, and an external magnetic field application unit for applying an external magnetic field to the magnetoresistance effect element. The magnetoresistance effect element includes a first ferromagnetic layer, a second ferromagnetic layer, and a spacer layer. The external magnetic field application unit includes a magnetization retention section and a magnetization setting section. The magnetization setting section has a function of setting a magnetization to be used to generate the external magnetic field into the magnetization retention section by applying a magnetization-setting magnetic field to the magnetization retention section and then stopping the application of the magnetization-setting magnetic field. The magnetization retention section has a function of retaining the set magnetization after the application of the magnetization-setting magnetic field is stopped.

### TECHNICAL FIELD

The present invention relates to a magnetoresistance effect device including a magnetoresistance effect element and an external magnetic field application unit for applying an external magnetic field to the magnetoresistance effect element.

### BACKGROUND ART

As the functionality of mobile communication devices such as mobile phones advances nowadays, wireless communications are becoming faster. Since communication speed is proportional to the bandwidth of the frequency band in use, the number of frequency bands needed for communication is increasing, and the number of high frequency filters, such as band-pass filters, to be mounted on a mobile communication device is also increasing accordingly.

On the other hand, spintronics, which utilizes the charge and spin of an electron at the same time, has recently been attracting attention as a technology possibly applicable to devices handling high frequency signals, or high frequency devices, such as high frequency filters. Among particularly notable spintronic techniques are ones using magnetoresistance effect elements having magnetoresistance effects, typified by the giant magnetoresistance (GMR) effect and tunnel magnetoresistance (TMR) effect. A magnetoresistance effect element typically includes two ferromagnetic layers and a spacer layer disposed between the two ferromagnetic layers. One of the two ferromagnetic layers of the magnetoresistance effect element is typically a magnetization pinned layer whose magnetization direction is pinned, and the other is a magnetization free layer whose magnetization direction changes with the direction of an external magnetic field.

If an electric current is supplied to a magnetoresistance effect element and the spin of one of two ferromagnetic materials is transmitted to the other ferromagnetic material, an energy called spin transfer torque (hereinafter, also referred to as SIT) rotates the spin of the other ferromagnetic material. STT acts on the magnetization of the aforementioned other ferromagnetic layer. If an external magnetic field is applied to the magnetoresistance effect element, torque from the external magnetic field also acts on the magnetization of the other ferromagnetic layer. If STT caused by a direct current and the torque caused by the external magnetic field counteract each other, the magnetization of the other ferromagnetic layer can oscillate at a specific frequency or with a specific period. This phenomenon is referred to as spin torque oscillation. Such an oscillation of the magnetization is a precessional motion, for example.

If energy fluctuating at a certain frequency, such as STT caused by a high frequency current, is applied to a ferromagnetic layer, there can occur a phenomenon in which the magnetization oscillates at a frequency specific to the ferromagnetic layer and the oscillation of the magnetization peaks in amplitude. Such a phenomenon is referred to as ferromagnetic resonance. The frequency of the oscillation of the magnetization at which the amplitude of the oscillation of the magnetization becomes maximum will hereinafter be referred to as a ferromagnetic resonance frequency. Examples of the energy causing ferromagnetic resonance include a high frequency current causing STT and a high frequency magnetic field.

For example, devices described in Patent Literatures 1 and 2 are known as high frequency devices using magnetoresistance effect elements.

Patent Literature 1 describes an oscillator including: a magnetoresistance effect element including a pinned layer (magnetization pinned layer), a spacer layer and a free layer (magnetization free layer); a bias magnetic field application unit for applying a bias magnetic field to the free layer; and an adjusting magnetic field application unit for applying an adjusting magnetic field to the free layer. Patent Literature 1 describes that the bias magnetic field application unit is a permanent magnet, an electromagnet or the like, and that the adjusting magnetic field application unit is an electromagnet or the like.

Patent Literature 2 describes a magnetic element including a magnetoresistance effect film, a pair of electrodes, at least two first soft magnetic layers, a coil as a magnetic field generation source, and a second soft magnetic layer. The magnetoresistance effect film includes a first ferromagnetic layer, a nonmagnetic spacer layer and a second ferromagnetic layer stacked. The pair of electrodes are disposed on opposite sides of the magnetoresistance effect film in the stacking direction. The magnetoresistance effect film is disposed between respective fore ends of the at least two first soft magnetic layers. The second soft magnetic layer has a ring-like shape. The coil is wound around the second soft magnetic layer. A part of each of the at least two first soft magnetic layers overlaps a part of the second soft magnetic layer in the stacking direction of the magnetoresistance effect film. The at least two first soft magnetic layers and the second soft magnetic layer are magnetically coupled to each other. In this magnetic element, a magnetic flux generated from the coil is captured by the second soft magnetic layer and the at least two first soft magnetic layers, and a magnetic field is applied to the magnetoresistance effect film from the at least two first soft magnetic layers.

Patent Literature 3 describes, although not a high frequency device using a magnetoresistance effect element, the following thin-film magnetic device. The thin-film magnetic device includes: a coil conductor to pass a pulse current through; a magnet layer formed near the coil conductor and having a magnetization that changes when the pulse current is applied to the coil conductor; a soft magnetic layer formed near the magnet layer with an insulation layer therebetween and configured to be subjected to a magnetic field formed by the magnet layer; and an inductor conductor layer formed over the soft magnetic layer with another insulation layer therebetween and having an inductance that changes in response to a change in permeability of the soft magnetic layer. Patent Literature 3 describes that the magnetization of the magnet layer can be changed by the amount of the pulse current, and the permeability of the soft magnetic layer and the ferromagnetic resonance frequency can be changed by the magnetic field formed by the magnet layer.

### CITATION LIST

### Patent Literature

Patent Literature 1: JP-A-2007-184923

Patent Literature 2: JP-A-2015-167224

Patent Literature 3: JP-A-2012-195327

### SUMMARY OF INVENTION

In a high frequency device using a magnetoresistance effect element, the oscillation frequency of the magnetization of the ferromagnetic layer and the ferromagnetic resonance frequency of the ferromagnetic layer of the magnetoresistance effect element can be changed by changing the magnitude of the external magnetic field applied to the ferromagnetic layer. A device that performs a predetermined function by using a magnetoresistance effect element is herein referred to as a magnetoresistance effect device. Examples of the predetermined function include resonance and filtering. Using the magnetoresistance effect device, a useful high frequency device such as a resonator with a variable resonance frequency and a band-pass filter with a variable passband can be constructed.

A permanent magnet or an electromagnet can be used as a means for generating an external magnetic field to be applied to the ferromagnetic layer of the magnetoresistance effect device. However, if a permanent magnet is used as the means for generating the external magnetic field, the magnitude of the external magnetic field cannot be easily changed. On the other hand, if an electromagnet is used as the means for generating the external magnetic field, a current needs to be continuously passed through the electromagnet while the external magnetic field is being generated, which presents a problem of increased power consumption.

It is an object of a certain embodiment to provide a magnetoresistance effect device that is capable of easily changing the magnitude of an external magnetic field applied to its magnetoresistance effect element and capable of reducing power consumption.

A magnetoresistance effect device of a certain embodiment includes a magnetoresistance effect element, and an external magnetic field application unit for applying an external magnetic field to the magnetoresistance effect element. The magnetoresistance effect element includes a first ferromagnetic layer having a first magnetization, a second ferromagnetic layer having a second magnetization, and a spacer layer disposed between the first ferromagnetic layer and the second ferromagnetic layer. At least one of the first and second magnetizations changes in direction depending on an effective magnetic field acting thereon.

The external magnetic field application unit includes a magnetization retention section and a magnetization setting section. The magnetization setting section has a function of setting a third magnetization to be used to generate the external magnetic field into the magnetization retention section by applying a magnetization-setting magnetic field to the magnetization retention section and then stopping the application of the magnetization-setting magnetic field. The magnetization retention section has a function of retaining the third magnetization after the application of the magnetization-setting magnetic field is stopped.

In the magnetoresistance effect device of a certain embodiment, the magnetization retention section may be formed of a semi-hard magnetic material or a hard magnetic material. The semi-hard magnetic material may have a coercivity within the range of 10 to 250 Oe (1 Oe=79.6 A/m). Further, the semi-hard magnetic material or the hard magnetic material may have a magnetic property such that the saturation magnetic field is higher than twice a coercivity.

In the magnetoresistance effect device of a certain embodiment, the magnetization retention section may have an end face facing the magnetoresistance effect element. The magnetoresistance effect element may be disposed such that the entirety of the magnetoresistance effect element is contained in a space that is defined by shifting an imaginary plane corresponding to the end face of the magnetization retention section in a direction parallel to the direction of the third magnetization.

In the magnetoresistance effect device of a certain embodiment, the magnetization setting section may be capable of changing the third magnetization in magnitude. In this case, the magnitude of the external magnetic field may change with the magnitude of the third magnetization. Further, the ferromagnetic resonance frequency of at least one of the first and second ferromagnetic layers may change with the magnitude of the external magnetic field. Further, the direction of the external magnetic field may change with the magnitude of the third magnetization.

In the magnetoresistance effect device of a certain embodiment, the magnetization setting section may include a yoke, and a coil wound around at least part of the yoke.

In the magnetoresistance effect device of a certain embodiment, the external magnetic field application unit may further include a permanent magnet. In this case, the external magnetic field may be a composite of a first magnetic field generated by the third magnetization and a second magnetic field generated by the permanent magnet.

The magnetoresistance effect device of a certain embodiment may further include an energy application unit for applying energy for oscillating at least one of the first and second magnetizations to the magnetoresistance effect element. The energy application unit may apply a high frequency current as the energy to the magnetoresistance effect element. Alternatively, the energy application unit may apply a high frequency magnetic field as the energy to the magnetoresistance effect element. The magnetoresistance effect device of a certain embodiment may further include an output port from which a high frequency output signal resulting from oscillation of the at least one of the first and second magnetizations comes out.

According to the magnetoresistance effect device of a certain embodiment, it is possible to easily change the third magnetization to be used to generate the external magnetic field. Further, according to a certain embodiment, while the third magnetization is kept unchanged, the magnetization-setting magnetic field does not need to be generated nor is the power for generating the magnetization-setting magnetic field needed. As a result, according to a certain embodiment, it is possible to provide a magnetoresistance effect device that is capable of easily changing the magnitude of the external magnetic field applied to its magnetoresistance effect element and capable of reducing power consumption.

### BRIEF DESCRIPTION OF DRAWINGS

FIG. 1 an explanatory diagram schematically showing a magnetoresistance effect device according to a first embodiment of the present invention.

FIG. 2 is a perspective view showing a magnetoresistance effect element and an external magnetic field application unit of the first embodiment of the present invention.

FIG. 3 is an explanatory diagram showing the positional relationship between a magnetization retention section and the magnetoresistance effect element in the first embodiment of the present invention.

FIG. 4 is a characteristic chart showing a magnetization curve of a magnetic material forming the magnetization retention section of the first embodiment of the present invention.

FIG. 5 is an explanatory diagram showing a first example of a method for setting a third magnetization of the first embodiment of the present invention.

FIG. 6 is a flowchart showing a second example of the method for setting the third magnetization of the first embodiment of the present invention.

FIG. 7 is an explanatory diagram for describing the second example shown in FIG. 6.

FIG. 8 is a waveform diagram showing changes of a coil current with time in the second example shown in FIG. 6.

FIG. 9 is a flowchart showing a third example of the method for setting the third magnetization of the first embodiment of the present invention.

FIG. 10 is a waveform diagram showing changes of the coil current with time in the third example shown in FIG. 9.

FIG. 11 is a characteristic chart showing the relationship between an external magnetic field and ferromagnetic resonance frequency in the first embodiment of the present invention.

FIG. 12 is an explanatory diagram schematically showing a magnetoresistance effect device according to a second embodiment of the present invention.

FIG. 13 is an explanatory diagram schematically showing a magnetoresistance effect device according to a third embodiment of the present invention.

FIG. 14 is a perspective view showing the main part of a magnetoresistance effect device according to a fourth embodiment of the present invention.

FIG. 15 is a perspective view showing the main part of a magnetoresistance effect device according to a fifth embodiment of the present invention.

FIG. 16 is a circuit diagram showing the circuit configuration of the magnetoresistance effect device according to the fifth embodiment of the present invention.

FIG. 17 is a perspective view showing the main part of a magnetoresistance effect device according to a sixth embodiment of the present invention.

FIG. 18 is an explanatory diagram for describing a magnetic field applied to a first ferromagnetic layer and a second ferromagnetic layer of the sixth embodiment of the present invention.

FIG. 19 is a perspective view showing the main part of a magnetoresistance effect device according to a seventh embodiment of the present invention.

### DESCRIPTION OF EMBODIMENTS

### First Embodiment

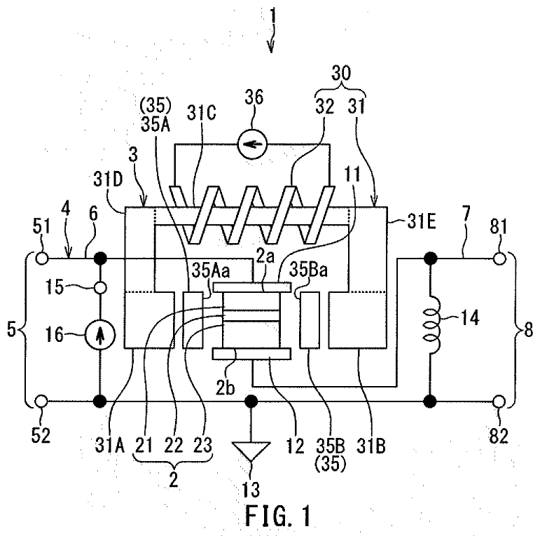

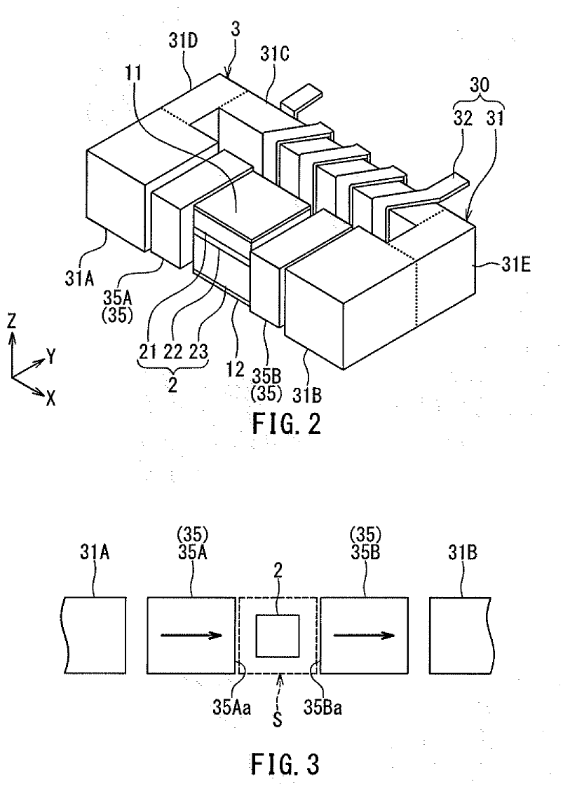

Embodiments of the present invention will now be described in detail with reference to the drawings. To begin with, the configuration of a magnetoresistance effect device according to a first embodiment of the present invention will be described with reference to FIG. 1 and FIG. 2. FIG. 1 is an explanatory diagram schematically showing the magnetoresistance effect device according to the present embodiment. FIG. 2 is a perspective view showing a magnetoresistance effect element and an external magnetic field application unit of the present embodiment. The magnetoresistance effect device 1 according to the present embodiment includes the magnetoresistance effect element 2, the external magnetic field application unit 3 for applying an external magnetic field to the magnetoresistance effect element 2, and an energy application unit 4.

As shown in FIG. 1 and FIG. 2, the magnetoresistance effect element 2 includes a first ferromagnetic layer 21 and a second ferromagnetic layer 23 each formed of a ferromagnetic material, and a spacer layer 22 disposed between the first ferromagnetic layer 21 and the second ferromagnetic layer 23. The first ferromagnetic layer 21 has a first magnetization, and the second ferromagnetic layer 23 has a second magnetization. At least one of the first and second magnetizations changes in direction depending on an effective magnetic field acting thereon. In the magnetoresistance effect element 2, the first magnetization and the second magnetization interact with each other to produce a magnetoresistance effect. Specifically, the magnetoresistance effect element 2 increases in resistance value as the relative angle between the direction of the first magnetization and the direction of the second magnetization increases from 0° toward 180°.

In the present embodiment, specifically, the first ferromagnetic layer 21 is a magnetization free layer, and the second ferromagnetic layer 23 is a magnetization pinned layer. Therefore, the direction of the first magnetization changes depending on an effective magnetic field acting thereon, whereas the direction of the second magnetization is pinned.

The effective magnetic field acting on the first magnetization is a composite of all kinds of magnetic fields acting on the first magnetization. The magnetic fields acting on the first magnetization include a magnetic anisotropy field, a coupling field, and a demagnetizing field, aside from the foregoing external magnetic field. In the present embodiment, the direction of the effective magnetic field acting on the first magnetization coincides or substantially coincides with the direction of the external magnetic field.

The magnetoresistance effect element 2 has a first end face 2a and a second end face 2b lying at opposite ends in the stacking direction of the layers constituting the magnetoresistance effect element 2. FIG. 1 and FIG. 2 show an example in which the second ferromagnetic layer 23, the spacer layer 22, and the first ferromagnetic layer 21 are stacked in this order, from closest to farthest from the second end face 2b. However, the first ferromagnetic layer 21, the spacer layer 22, and the second ferromagnetic layer 23 may be stacked in this order, from closest to farthest from the second end face 2b.

Now, we define an X direction, a Y direction, and a Z direction as shown in FIG. 2. The X direction, the Y direction, and the Z direction are orthogonal to one another. In the present embodiment, the Z direction is defined as the direction perpendicular to the interface between the second ferromagnetic layer 23 and the spacer layer 22 and toward the first ferromagnetic layer 21 from the second ferromagnetic layer 23. Both the X and Y directions are parallel to the aforementioned interface. The opposite direction to the X direction will be referred to as −X direction; the opposite direction to the Y direction will be referred to as −Y direction; and the opposite direction to the Z direction will be referred to as −Z direction. As used herein, the term “above” refers to positions located forward of a reference position in the Z direction, and “below” refers to positions opposite to “above” with respect to the reference position.

The energy application unit 4 is to apply energy for oscillating at least one of the first and second magnetizations to the magnetoresistance effect element 2. In the present embodiment, specifically, the energy application unit 4 applies energy for oscillating the first magnetization to the magnetoresistance effect element 2. Further, in the present embodiment, a high frequency current is used as the energy for oscillating the first magnetization. The energy application unit 4 is configured to be able to apply a high frequency current as the energy to the magnetoresistance effect element 2. Specifically, the energy application unit 4 includes an input port 5 for receiving a high frequency input signal, and a first signal line 6 for transmitting a high frequency current based on the high frequency input signal received at the input port 5 to the magnetoresistance effect element 2. The high frequency input signal is, for example, a signal having a frequency of 100 MHz or higher. The frequency of the high frequency current is equal to the frequency of the high frequency input signal.

The magnetoresistance effect device 1 further includes an output port 8 and a second signal line 7. The magnetoresistance effect element 2 generates a high frequency output signal resulting from oscillation of at least one of the first and second magnetizations. In the present embodiment, specifically, the high frequency output signal results from the oscillation of the first magnetization. The second signal line 7 transmits the high frequency output signal from the magnetoresistance effect element 2 to the output port 8. The high frequency output signal comes out from the output port 8. The magnetoresistance effect element 2 is located between the input port 5 and the output port 8 in circuit configuration.

The magnetoresistance effect device 1 further includes a first electrode 11, a second electrode 12, and a ground electrode 13. The first electrode 11 and the second electrode 12 are disposed with the magnetoresistance effect element 2 interposed therebetween. The first electrode 11 and the second electrode 12 are used to feed the high frequency current and a direct current to be described later through the magnetoresistance effect element 2. The first electrode 11 is in contact with the first end face 2a of the magnetoresistance effect element 2. The second electrode 12 is in contact tie the second end face 2b of the magnetoresistance effect element 2. The direct current flows in a direction intersecting the plane of the layers constituting the magnetoresistance effect element 2, e.g., in a direction perpendicular to the plane of the layers constituting the magnetoresistance effect element 2.

In the example shown in FIG. 1, the input port 5 has a pair of terminals 51 and 52. One end of the first signal line 6 is electrically connected to the terminal 51. The other end of the first signal line 6 is electrically connected to the first electrode 11.

In the example shown in FIG. 1, the output port 8 has a pair of terminals 81 and 82. One end of the second signal line 7 is electrically connected to the terminal 81. The other end of the second signal line 7 is electrically connected to the second electrode 12.

The terminal 52 of the input port 5 and the terminal 82 of the output port 8 are each electrically connected to the ground electrode 13. The potential of the ground electrode 13 is used as a reference potential.

The first and second electrodes 11 and 12 may be formed of, for example, a single-layered film of any one of Ta, Cu, Au, AuCu, Ru, Al and Cr, or a stack of a plurality of films each made of any one of these materials.

The signal lines 6 and 7 and the ground electrode 13 may be formed of microstrip lines or coplanar waveguides.

The magnetoresistance effect device 1 further includes a choke coil 14 and a direct current input terminal 15. One end of the choke coil 14 is electrically connected to the second signal line 7. The other end of the choke coil 14 is electrically connected to the ground electrode 13. The direct current input terminal 15 is electrically connected to the first signal line 6. In circuit configuration, the magnetoresistance effect element 2 is located between the direct current input terminal 15 and the choke coil 14. A direct current is input to the direct current input terminal 15, and the direct current is supplied to the magnetoresistance effect element 2.

The choke coil 14 has an inductance. This causes the impedance of the choke coil 14 to increase with increasing frequency of the current passing through the choke coil 14. The choke coil 14 thus passes the direct current passing through the signal line 7 and feeds the direct current through the ground electrode 13, and on the other hand, presents a high impedance to the high frequency output signal passing through the second signal line 7.

For example, a chip inductor or a line is used as the choke coil 14. The inductance of the choke coil 14 is preferably 10 nH or higher. Note that the magnetoresistance effect device 1 may include a resistor element having an inductance component, in place of the choke coil 14.

To effect the operation of the magnetoresistance effect device 1, as shown in FIG. 1, a direct current source 16 is provided between the direct current input terminal 15 and the ground electrode 13. As a result, there is formed a closed circuit including the direct current source 16, the direct current input terminal 15, the first signal line 6, the magnetoresistance effect element 2, the second signal line 7, the choke coil 14 and the ground electrode 13. The direct current source 16 generates a direct current to flow through this closed circuit. In the magnetoresistance effect element 2, the direct current flows in the direction from the first ferromagnetic layer 21 to the second ferromagnetic layer 23.

The direct current source 16 is constructed of, for example, a circuit that combines a direct-current voltage source and a resistor. A variable resistor or a fixed resistor is used as the resistor. If a variable resistor is used, the magnitude of the direct current is changeable. If a fixed resistor is used, the direct current has a constant value. A choke coil or a resistor element having an inductance component may be provided between the direct current input terminal 15 and the direct current source 16 in order to prevent a high frequency current that passes through the first signal line 6 from flowing into the direct current source 16.

Now, the magnetoresistance effect element 2 will be described in further detail. The first ferromagnetic layer 21 has an easy axis of magnetization. The easy axis of magnetization of the first ferromagnetic layer 21 may be in a direction parallel to the interface between the first ferromagnetic layer 21 and the spacer layer 22, or perpendicular to the interface between the first ferromagnetic layer 21 and the spacer layer 22.

In the ease where the direction of the easy axis of magnetization of the first ferromagnetic layer 21 is parallel to the interface between the first ferromagnetic layer 21 and the spacer layer 22, examples of the ferromagnetic material forming the first ferromagnetic layer 21 include high spin-polarization materials such as CoFe, NiFe, CoFeB, FeB, CoFeSi, CoMnGe, CoMnSi and CoMnAl, and Heusler alloys. In such a case, the first ferromagnetic layer 21 preferably has a thickness within the range of 0.1 to 50 nm.

In the case where the direction of the easy axis of magnetization of the first ferromagnetic layer 21 is perpendicular to the interface between the first ferromagnetic layer 21 and the spacer layer 22, the first ferromagnetic layer 21 can be formed of, for example, a film of Co, FeB, a CoCr-based alloy, a CoCrPt-based alloy, an FePt-based alloy, an SmCo-based alloy containing rare earth metals, a TbFeCo-based alloy or a Heusler alloy, a multi-layered film of Co, a Co/Pt artificial lattice film, a Co/Pd artificial lattice film, or an Fe/Pd artificial lattice film. Such films are preferably 0.1 to 50 nm thick.

The first ferromagnetic layer 21 may be composed of a plurality of layers. In such a case, one of the plurality of layers that is closest to the spacer layer 22 is preferably a high spin-polarization layer having a higher spin polarization than the other one or more layers. This makes it possible to increase the resistance change ratio of the magnetoresistance effect element 2. A high spin-polarization material such as a CoFe alloy, a CoFeB alloy or the like is used as the material of the high spin-polarization layer. The high spin-polarization layer preferably has a thickness within the range of 0.1 to 1.5 nm.

As the ferromagnetic material forming the second ferromagnetic layer 23, it is preferable to use a high spin-polarization material such as Fe, Co, Ni, an alloy of Ni and Fe, an alloy of Fe and Co, an alloy of Fe, Co and B, or the like. This makes it possible to increase the resistance change ratio of the magnetoresistance effect element 2. A Heusler alloy may also be used as the ferromagnetic material forming the second ferromagnetic layer 23. The second ferromagnetic layer 23 preferably has a thickness within the range of 1 to 50 nm.

The second ferromagnetic layer 23 may also be formed of a perpendicular magnetization film. In such a case, the second ferromagnetic layer 23 can be formed of, for example, a film of Co, a CoCr-based alloy, a CoCrPt-based alloy, an FePt-based alloy, an SmCo-based alloy containing rare earth metals or a TbFeCo-based alloy, a multi-layered film of Co, a Co/Pt artificial lattice film, a Co/Pd artificial lattice film, or an Fe/Pd artificial lattice film.

The magnetoresistance effect element 2 may further include an antiferromagnetic layer for pinning the direction of the second magnetization of the second ferromagnetic layer 23. The antiferromagnetic layer is provided to be in contact with a surface of the second ferromagnetic layer 23 opposite to the surface thereof in contact with the spacer layer 22. The antiferromagnetic layer pins the direction of the second magnetization of the second ferromagnetic layer 23 by means of exchange coupling with the second ferromagnetic layer 23. For example, any one of FeO, CoO, NiO, CuFeS₂, IrMn, FeMn, PtMn, Cr and Mn can be used as the material of the antiferromagnetic layer.

The direction of the second magnetization of the second ferromagnetic layer 23 may be pinned by magnetic anisotropy of the second ferromagnetic layer 23 based on its crystalline structure, shape or other factors, without using the antiferromagnetic layer.

The spacer layer 22 may be formed of a nonmagnetic material in its entirety. The nonmagnetic material forming the spacer layer 22 may be a conductive material, an insulating material or a semiconductor material.

Examples of nonmagnetic conductive materials usable to form the spacer layer 22 include Cu, Ag, Au, Cr, and Ru. If the spacer layer 22 is formed of a nonmagnetic conductive material, a giant magnetoresistance (GMR) effect occurs in the magnetoresistance effect element 2. The spacer layer 22 in such a case preferably has a thickness within the range of 0.5 to 3.0 nm.

Example of nonmagnetic insulating materials usable to form the spacer layer 22 include AlOₓ, MgO, MgAlOₓ, and TiOₓ. In AlOₓ, MgAlOₓ and TiOₓ, x is any number greater than 0. If the spacer layer 22 is formed of a nonmagnetic insulating material, a tunneling magnetoresistance (TMR) effect occurs in the magnetoresistance effect element 2. The spacer layer 22 in such a case preferably has a thickness within the range of 0.5 to 3.0 nm.

Example of nonmagnetic semiconductor materials usable to form the spacer layer 22 include ZnOₓ, InOₓ, SnOₓ, SbOₓ, GaOₓ, indium tin oxide (ITO), AlN, TiN, and GaN. In ZnOₓ, InOₓ, SnOₓ, SbOₓ and GaOₓ, x is any number greater than 0. When the spacer layer 22 is formed of a nonmagnetic semiconductor material, the spacer layer 22 preferably has a thickness within the range of 0.5 to 4.0 nm.

The spacer layer 22 may include an insulating part formed of an insulating material and one or more current-carrying parts formed of a conductive material and provided in the insulating part. Examples of the insulating material forming the insulating part include Al₂O₃ and MgO. Examples of the conductive material forming the current-carrying parts include CoFe, CoFeB, CoFeSi, CoMnGe, CoMnSi, CoMnAl, Fe, Co, Au, Cu, Al, and Mg. The spacer layer 22 in such a case preferably has a thickness within the range of 0.5 to 2.0 nm.

The magnetoresistance effect element 2 may further include first and second metal layers. The first metal layer is provided between the first ferromagnetic layer 21 and the first electrode 11. The second metal layer is provided between the second ferromagnetic layer 23 and the second electrode 12. The first metal layer is used as a cap layer. The second metal layer is used as a seed layer or buffer layer. The first and second metal layers are formed of, for example, a single-layered film or multi-layered film containing one or more of Ru, Ta, Cu, Cr, and NiCr. The first and second metal layers preferably have thicknesses in the range of 1 to 20 nm.

Next, the configuration of the external magnetic field application unit 3 will be described with reference to FIG. 1 and FIG. 2. The external magnetic field application unit 3 includes a magnetization retention section 35 and a magnetization setting section 30. The magnetization setting section 30 has the function of setting a third magnetization to be used to generate the external magnetic field into the magnetization retention section 35 by applying a magnetization-setting magnetic field to the magnetization retention section 35 and then stopping the application of the magnetization-setting magnetic field.

The magnetization retention section 35 has the function of retaining the third magnetization after the application of the magnetization-setting magnetic field is stopped. The magnetization retention section 35 may be formed of a semi-hard magnetic material or a hard magnetic material.

In the present embodiment, the magnetization retention section 35 includes a first portion 35A and a second portion 35B. In this case, both the first portion 35A and the second portion 35B are formed of a semi-hard magnetic material or a hard magnetic material. The third magnetization is set into each of the first portion 35A and the second portion 35B by the magnetization setting section 30. As shown in FIG. 2, the first portion 35A and the second portion 35B are located on opposite sides of the magnetoresistance effect element 2 in the X direction.

The first and second portions 35A and 35B have their respective end faces 35Aa and 35Ba facing the magnetoresistance effect element 2. Since the first and second portions 35A and 35B are portions of the magnetization retention section 35, one can say that the magnetization retention section 35 has the end faces 35Aa and 35Ba.

In terms of magnetic properties such as residual magnetization and coercivity, the semi-hard magnetic material forming the magnetization retention section 35 is a magnetic material that exhibits properties intermediate between those of a soft magnetic material and a hard magnetic material. The semi-hard magnetic material preferably has a residual magnetization in the range of 0.1 to 20 kG (1 G=1 kA/m). The semi-hard magnetic material preferably has a coercivity in the range of 10 to 250 Oe. The semi-hard magnetic material preferably has a squareness ratio in the range of 0.5 to 1. Squareness ratio is the ratio Mr/Ms of residual magnetization Mr to saturation magnetization Ms.

Examples of a magnetic material forming the semi-hard magnetic material include Fe, Co, Ni, an alloy composed of two or all of Fe, Co and Ni, and an alloy containing two or all of Fe, Co and Ni and other elements than Fe, Co and Ni. Examples of the elements other than Fe, Co and Ni include Ta, Nb, Mo, Au, Cu, Ti, Be, Al, B, Sm, W, Cr, Mn, and V. Specific examples of the alloy containing two or all of Fe, Co and Ni and other elements than Fe, Co and Ni include a CuNiCo alloy, a CuNiFe alloy, an FeCoV alloy, and an FeCoCr alloy.

The hard magnetic material forming the magnetization retention section 35 preferably has a coercivity higher than 250 Oe. The coercivity of the hard magnetic material is preferably 4000 Oe or lower, more preferably 1000 Oe or lower.

Examples of a magnetic material forming the hard magnetic material include a CoPt alloy, a CoCrPt alloy, an AlNiCo alloy, an NdFeB alloy, and an SmCo alloy.

The first and second portions 35A and 35B are preferably 0.1 to 10 μm thick in the Z direction. The first and second portions 35A and 35B preferably have magnetic anisotropy in a direction parallel to the direction of the third magnetization. The first and second portions 35A and 35B can be formed by, for example, sputtering, ion beam deposition or frame plating.

The magnetization setting section 30 has a yoke 31 and a coil 32 wound around at least part of the yoke 31. The yoke 31 is formed of a soft magnetic material. In the present embodiment, the yoke 31 includes a first pole section 31A, a second pole section 31B, a core section 31C, a first coupling section 31D, and a second coupling section 31E.

As shown in FIG. 2, the first pole section 31A and the second pole section 31B are disposed with the first portion 35A, the magnetoresistance effect element 2 and the second portion 35B interposed therebetween. Specifically, the first pole section 31A, the first portion 35A, the magnetoresistance effect element 2, the second portion 35B, and the second pole section 31B are arranged in this order in a row along the X direction.

The core section 31C has a shape elongated in the X direction, and is located at a distance from the magnetoresistance effect element 2 in the Y direction. The first coupling section 31D couples one end of the core section 31C to the first pole section 31A. the second coupling section 31E couples the other end of the core section 31C to the second pole section 31B.

In FIG. 1 and FIG. 2, the boundary between the first pole section 31A and the first coupling section 31D, the boundary between the second pole section 31B and the second coupling section 31E, the boundary between the first coupling section 31D and the core section 31C, and the boundary between the second coupling section 31E and the core section 31C are shown by dotted lines. For example, all of the first pole section 31A, the second pole section 31B, the core section 31C, the first coupling section 31D and the second coupling section 31E have a rectangular parallelepiped shape.

The soft magnetic material used to form the yoke 31 may be, for example, NiFe, NiFeCo, NiFeX (X is Ta, Nb or Mo), FeCO, CoZrNb, CoAl—O, Fe—SiO₂ or CoFeB. The yoke 31 is preferably 0.1 to 10 μm thick in the Z direction. The yoke 31 can be formed by, for example, sputtering, ion beam deposition or frame plating.

The coil 32 is wound around the core section 31C. The coil 32 is formed of a conductive material. A non-illustrated insulating film is interposed between the coil 32 and the core section 31C. The conductive material used to form the coil 32 may be, for example, Au, Cu, Al, or an alloy such as AlCu.

The coil 32 has a plurality of upper wires located above the core section 31C, a plurality of lower wires located below the core section 31C, and a plurality of side wires located on both sides of the core section 31C in the Y direction. The plurality of upper wires, lower wires and side wires are connected to constitute a winding extending around the core section 31C. The plurality of upper wires, lower wires and side wires are each preferably 0.1 to 10 μm thick in the Z direction. The plurality of upper wires, lower wires and side wires can be formed by, for example, sputtering, ion beam deposition or frame plating.

The plurality of side wires may be formed of the same materials as the yoke 31. In such a case, it becomes possible to form the plurality of side wires and the yoke 31 simultaneously.

The coil 32 may be wound around the coupling sections 31D and 31E or around the pole sections 31A and 31B. To allow a larger magnetization-setting magnetic field to be applied to the first and second portions 35A and 35B of the magnetization retention section 35 without increasing the number of turns, the coil 32 serving as the magnetic field generation source is preferably disposed closer to the first and second portions 35A and 35B.

To apply a magnetization-setting magnetic field to the magnetization retention section 35, a direct current source 36 is connected to the coil 32, as shown in FIG. 1. By passing a current through the coil 32 using the direct current source 36, a magnetization-setting magnetic field is generated between the first pole section 31A and the second pole section 31B of the yoke 31. This magnetization-setting magnetic field is used to set the third magnetization into each of the first and second portions 35A and 35B of the magnetization retention section 35.

Hereinafter, a current passed through the coil 32 using the direct current source 36 will be referred to as a coil current. The magnitude of the magnetization-setting magnetic field is changeable by adjusting the magnitude of the coil current. The direction of the magnetization-setting magnetic field is switchable between the direction from the first pole section 31A to the second pole section 31B and the opposite direction by changing the direction of the coil current. In this way, the magnetization setting section 30 is capable of changing the magnitude and direction of the magnetization-setting magnetic field, and thereby changing the magnitude and direction of the third magnetization.

Next, the operation and effects of the magnetoresistance effect device 1 according to the present embodiment will be described. In the present embodiment, it is possible to generate ferromagnetic resonance in the first ferromagnetic layer 21 of the magnetoresistance effect element 2 by applying energy that fluctuates at a frequency equal to the ferromagnetic resonance frequency of the first ferromagnetic layer 21 to the magnetoresistance effect element 2.

In the present embodiment, in particular, a high frequency current is used as the foregoing energy. The high frequency current is superposed on the direct current flowing through the magnetoresistance effect element 2 and applied to the magnetoresistance effect element 2. Once the high frequency current has been applied to the magnetoresistance effect element 2, the current density in the first ferromagnetic layer 21 changes at the frequency of the high frequency current. As a result, the STT acting on the first magnetization of the first ferromagnetic layer 21 changes at the frequency of the high frequency current. This causes the first magnetization to oscillate at the frequency of the high frequency current so that its direction changes.

The magnetoresistance effect element 2 generates a high frequency output signal resulting from the oscillation of the first magnetization. The high frequency output signal has a frequency equal to that of the high frequency input signal. The high frequency output signal is transmitted from the magnetoresistance effect element 2 to the output port 8 by the second signal line 7. This high frequency output signal comes out from the output port 8.

More specifically, the oscillation of the first magnetization changes the angle that the direction of the first magnetization forms with respect to the direction of the second magnetization of the second ferromagnetic layer 23, and consequently changes the resistance value of the magnetoresistance effect element 2. The high frequency output signal is generated by the change in the resistance value of the magnetoresistance effect element 2. In the present embodiment, specifically, the high frequency output signal appears as a change in potential at the terminal 81 of the output port 8.

If the frequency of the high frequency input signal is equal to the ferromagnetic resonance frequency of the first ferromagnetic layer 21, ferromagnetic resonance occurs in the first ferromagnetic layer 21 to maximize the amplitude of the oscillation of the first magnetization. As a result, the amplitude of the high frequency output signal also becomes maximum.

The ferromagnetic resonance frequency of the first ferromagnetic layer 21 can be changed by, for example, changing the magnitude of an effective magnetic field acting on the first ferromagnetic layer 21. In the present embodiment, the magnitude of the effective magnetic field acting on the first ferromagnetic layer 21 depends on the magnitude of the external magnetic field applied to the magnetoresistance effect element 2 by the external magnetic field application unit 3. Therefore, in the present embodiment the ferromagnetic resonance frequency of the first ferromagnetic layer 21 can be changed by, for example, changing the magnitude of the external magnetic field applied to the magnetoresistance effect element 2. More specifically, enhancing the external magnetic field increases the ferromagnetic resonance frequency.

The operation of the external magnetic field application unit 3 will be described in detail below. The external magnetic field is generated by the third magnetization set into each of the first and second portions 35A and 35B of the magnetization retention section 35. The direction of the external magnetic field coincides or substantially coincides with the direction of the third magnetization set into each of the first and second portions 35A and 35B of the magnetization retention section 35.

The magnetization setting section 30 sets the third magnetization into each of the first and second portions 35A and 35B by applying the magnetization-setting magnetic field to the first and second portions 35A and 35B and then stopping the application of the magnetization-setting magnetic field. The magnitude and direction of the magnetization-setting magnetic field can be changed by the magnitude and direction of the coil current.

Thus, the external magnetic field application unit 3 can change the magnitude and direction of the third magnetization by changing the magnitude and direction of the magnetization-setting magnetic field with the magnetization setting section 30, and can consequently change the magnitude and direction of the external magnetic field.

The first and second portions 35A and 35B retain the third magnetization after the application of the magnetization-setting magnetic field is stopped. Therefore, according to the present embodiment, while the external magnetic field is kept unchanged, that is, while the third magnetization is kept unchanged, there is no need to generate the magnetization-setting magnetic field and no need to pass a current through the coil 32 of the magnetization setting section 30. In other words, while the external magnetic field is kept unchanged, the external magnetic field application unit 3 does not need power for generating the magnetization-setting magnetic field. The magnetoresistance effect device 1 according to the present embodiment is thus capable of easily changing the magnitude of the external magnetic field applied to its magnetoresistance effect element and capable of reducing power consumption.

It is desirable that a spatially uniform external magnetic field be applied to the magnetoresistance effect element 2. A desirable layout of the magnetization retention section 35 and the magnetoresistance effect element 2 for achieving this will now be described with reference to FIG. 3. FIG. 3 is an explanatory diagram showing the positional relationship between the magnetization retention section 35 and the magnetoresistance effect element 2. In FIG. 3 the arrows drawn inside the first and second portions 35A and 35B represent the third magnetization. First, the area of each of the end faces 35Aa and 35Ba of the first and second portions 35A and 35B is preferably larger than the area of a cross section of the magnetoresistance effect element 2 perpendicular to the direction of the third magnetization. Besides, the magnetoresistance effect element 2 is preferably disposed such that the entirety of the magnetoresistance effect element 2 is contained in a space S that is defined by shifting two imaginary planes corresponding to the end faces 35Aa and 35Ba in a direction parallel to the direction of the third magnetization. This makes it possible to apply a spatially uniform external field to the magnetoresistance effect element 2 using the first and second portions 35A and 35B.

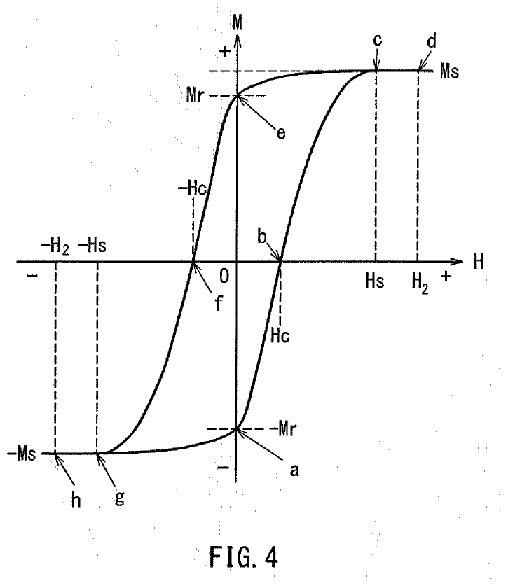

Next, the magnetic property of the semi-hard magnetic material or hard magnetic material forming the magnetization retention section 35 will be described with reference to FIG. 4. Hereinafter, the semi-hard magnetic material or hard-magnetic material forming the magnetization retention section 35 will be referred to as a magnetic material 35M. FIG. 4 shows an example of the magnetization curve of the magnetic material 35M. In FIG. 4 the horizontal axis represents a magnetic field H applied to the magnetic material 35M, and the vertical axis represents the magnetization M of the magnetic material 35M. For both of the magnetic field H and the magnetization M, the magnitude in a predetermined direction will be expressed in a positive value, and the magnitude in the opposite direction to the predetermined direction will be expressed in a negative value.

The residual magnetization, saturation magnetization, coercivity, and saturation magnetic field of the magnetic material 35M will be denoted by the symbols Mr, Ms, He, and Hs, respectively. If the magnetic material 35M has the property shown in FIG. 4, for example, the magnetization M increases as the magnetic field H is increased from the state of point a where the magnetic field H is 0 and the magnetization M is −Mr. The magnetization M then goes through the state of point b where the magnetic field H is He and the magnetization M is 0, and reaches Ms in the state of point c where the magnetic field H is Hs. The magnetization M then remains at Ms even if the magnetic field H is increased up to the state of point d where the magnetic field H is H₂.

If the magnetic field H is reduced from the state of point d, the magnetization M does not change until the state of point c is reached. The magnetization M then decreases to the state of point e where the magnetic field H is 0 and the magnetization M is Mr. If the magnetic field H is reduced from the state of point e into a negative value and its magnitude (absolute value of the magnetic field H) is increased, the magnetization M goes through the state of point f where the magnetic field H is −He and the magnetization M is 0, and then the magnetization M reaches −Ms in the state of point g where the magnetic field H is −Hs. The magnetization M then remains at −Ms even if the absolute value of the negative-valued magnetic field H is increased up to the state of point h where the magnetic field H is −H₂. If the absolute value of the negative-valued magnetic field H is reduced from the state of point h, the magnetization M does not change until the state of point g is reached. The magnetization M then increases to the state of point a where the magnetic field H is 0 and the magnetization M is −Mr. In such a manner, the magnetization curve of the magnetic material 35M traces a hysteresis curve.

The magnetic material 35M desirably has a magnetic property such that the saturation magnetic field Hs is higher than twice the coercivity Hc. This makes it possible to reduce a variation in the magnitude of the third magnetization relative to a variation in the magnetization-setting magnetic field.

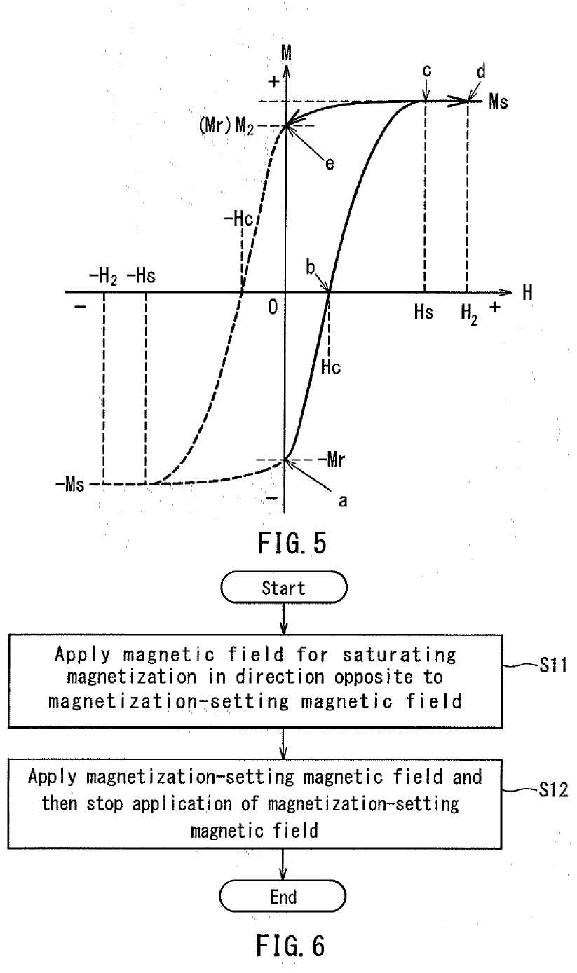

First to third examples of a method for setting the third magnetization will be described below. First, with reference to FIG. 5, the first example of the method for setting the third magnetization will be described. FIG. 5 is an explanatory diagram showing the first example of the method for setting the third magnetization. FIG. 5 corresponds to the magnetization curve shown in FIG. 4. Points a, b, c, d, and e shown in FIG. 4 are also shown in FIG. 5. The first example is an example in which the third magnetization is set to M₂ equal to the residual magnetization Mr. In the first example, the magnetization-setting magnetic field is set to a value such that the magnetization of the magnetic material 35M fully reaches the saturation magnetization Ms regardless of the value of the third magnetization before being set to the new value M₂. FIG. 5 shows an example in which the value of the third magnetization before being set to the new value M₂ is −Mr and the magnetization-setting magnetic field is set to H₂. The application of the magnetization-setting magnetic field is then stopped. This causes the magnetic material 35M to transition from the state of point d in FIG. 5 to reach the state of point e via the state of point c. The magnetization of the magnetic material 35M thus becomes M₂ equal to the residual magnetization Mr, and such a state is maintained. In this way, the third magnetization is set to M₂.

To set the third magnetization to a value equal to −Mr, the magnetization-setting magnetic field is set to a value such that the magnetization of the magnetic material 35M fully reaches −Ms regardless of the value of the third magnetization before being set to the new value M₂, and then the application of the magnetization-setting magnetic field is stopped.

Next, the second example of the method for setting the third magnetization will be described with reference to FIGS. 6 and 7. FIG. 6 is a flowchart showing the second example of the method for setting the third magnetization. FIG. 7 is an explanatory diagram for describing the second example. FIG. 7 corresponds to the magnetization curve shown in FIG. 4. The second example is an example in which the third magnetization is set to M₁ that is smaller than the residual magnetization Mr.

As shown in FIG. 6, the second example includes step S11 where a magnetic field for saturating magnetization is applied in a direction opposite to the magnetization-setting magnetic field, and step S12 where a magnetization-setting magnetic field is applied and then the application of the magnetization-setting magnetic field is stopped. FIG. 7 shows an example in which in accordance with step S11, a negative-valued magnetic field −H₂ is applied so that the magnetization of the magnetic material 35M fully reaches −Ms, and then, in accordance with step S12, a magnetization-setting magnetic field H₁ is applied and then the application of the magnetization-setting magnetic field H₁ is stopped. Once the application of the magnetization-setting magnetic field H₁ has been stopped, the magnetization of the magnetic material 35M becomes M₁, and such a state is maintained. In this way, the third magnetization is set to M₁.

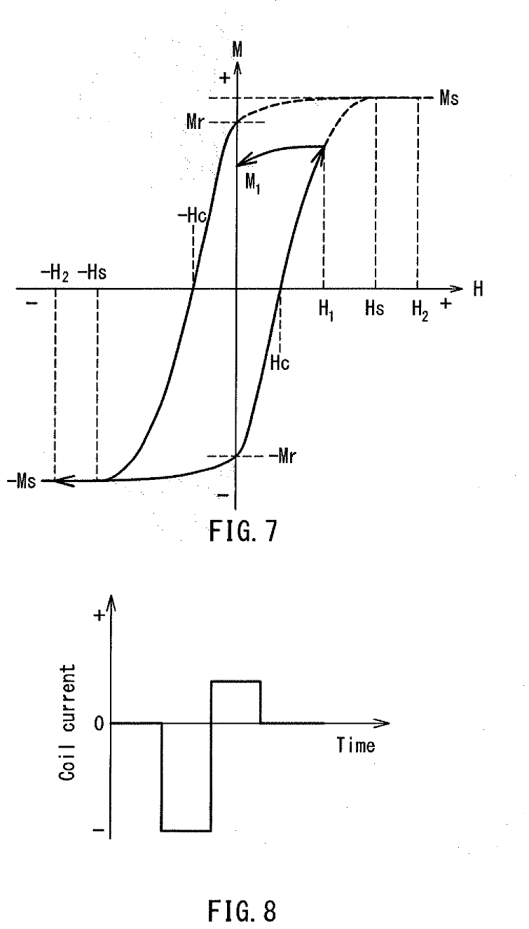

The magnitude and direction of the magnetic field applied to the magnetic material 35M can be set by the magnitude and direction of the coil current flowing through the coil 32. The magnitude of the coil current in a direction such that the magnetic field applied to the magnetic material 35M has a positive value will be expressed in a positive value. The magnitude of the coil current in a direction such that the magnetic field applied to the magnetic material 35M has a negative value will be expressed in a negative value. The magnitude of the magnetic field applied to the magnetic material 35M depends on the magnitude of the coil current. FIG. 8 is a waveform diagram showing changes of the coil current with time in the second example. In the second example, as shown in FIG. 8, a negative-valued coil current having a magnitude such that the magnetic field applied to the magnetic material 35M becomes −H₂ is supplied for a certain duration of time, and then a positive-valued coil current having a magnitude such that the magnetic field applied to the magnetic material 35M becomes H₁ is supplied for a certain duration of time. The supply of the coil current is then stopped.

To set the third magnetization to a negative value greater than −Mr, a positive-valued magnetic field is applied so that the magnetization of the magnetic material 35M fully reaches Ms, and then a magnetization-setting magnetic field having a negative value is applied. The application of the magnetization-setting magnetic field is then stopped.

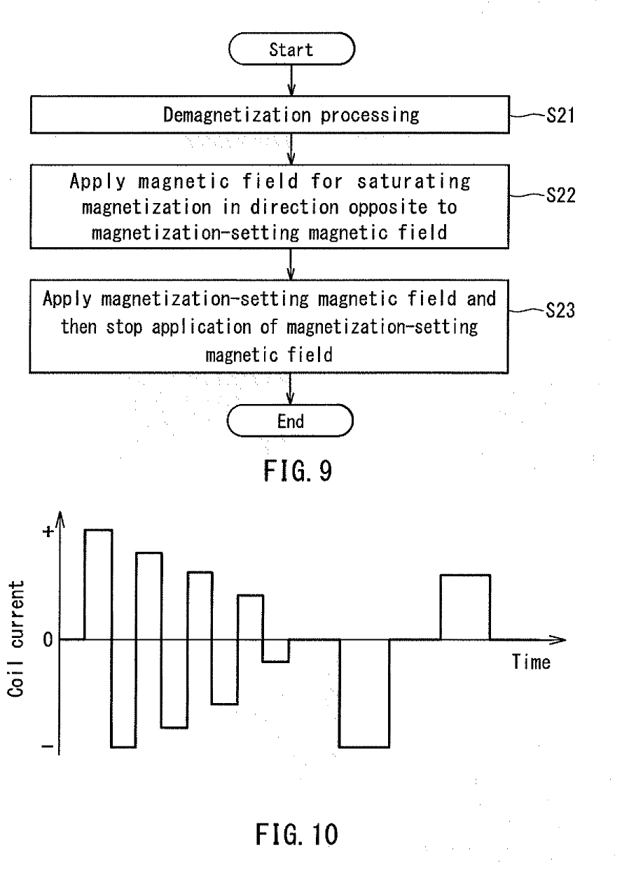

Next, the third example of the method for setting the third magnetization will be described with reference to FIGS. 9 and 10. FIG. 9 is a flowchart showing the third example of the method for setting the third magnetization. FIG. 10 is a waveform diagram showing changes of the coil current with time in the third example. The third example is an example in which the third magnetization is set to M₁ that is smaller than the residual magnetization Mr, like the second example.

As shown in FIG. 9, the third example includes step S21 where demagnetization processing is performed, step S22 where a magnetic field for saturating magnetization is applied in a direction opposite to the magnetization-setting magnetic field, and step S23 where the magnetization-setting magnetic field is applied. The demagnetization processing in step S21 is processing to initially apply a magnetic field having a large value and then reduce the magnitude of the magnetic field (the absolute value of the magnetic field) while repeatedly reversing the direction of the magnetic field. Specifically, as shown in FIG. 10, a coil current having a large value is initially supplied, and then the magnitude of the coil current (the absolute value of the coil current) is reduced while the direction of the coil current is repeatedly reversed. This can reduce the value of the magnetization of the magnetic material 35M to zero while spatially uniformizing the magnetization inside the magnetic material 35M. The details of steps S22 and S23 are the same as those of steps S11 and S12 in the second example.

According to the third example, it is possible to prevent the occurrence of spatial variations of the external magnetic field due to spatial variations of the magnetization inside the magnetic material 35M. As a result, it becomes possible to apply a spatially uniform external magnetic field to the magnetoresistance effect element 2.

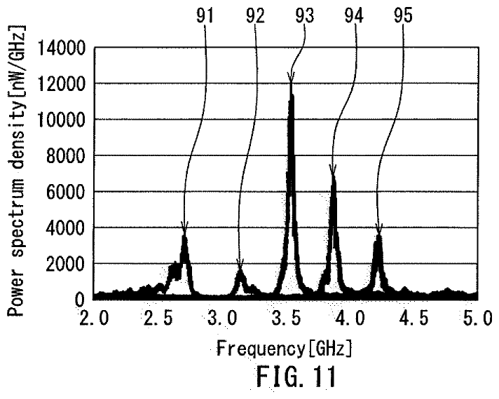

Next, reference is made to FIG. 11 to describe the relationship between the magnitude of the external magnetic field applied to the magnetoresistance effect element 2 and the ferromagnetic resonance frequency of the first ferromagnetic layer 21. As described previously, the ferromagnetic resonance frequency of the first ferromagnetic layer 21 can be changed by changing the magnitude of the external magnetic field applied to the magnetoresistance effect element 2. FIG. 11 is a characteristic chart showing an example of the relationship between the external magnetic field and the ferromagnetic resonance frequency. In FIG. 11 the horizontal axis represents frequency, and the vertical axis represents power spectrum density. The waveforms denoted by reference numerals 91, 92, 93, 94, and 95 represent the relationship between the frequency and power spectrum density when the magnitude of the external magnetic field is set to 400 Oe, 500 Oe, 600 Oe, 700 Oe, and 800 Oe, respectively. The frequency at which the waveform peaks corresponds to the ferromagnetic resonance frequency of the first ferromagnetic layer 21. As shown in FIG. 11, the ferromagnetic resonance frequency increases with increasing external magnetic field. In the example shown in FIG. 11, the ferromagnetic resonance frequency is 2.6 GHz when the magnitude of the external magnetic field is 400 Oe, and 4.2 GHz when the magnitude of the external magnetic field is 800 Oe. Therefore, in this example, changing the magnitude of the external magnetic field over the range of 400 to 800 Oe allows the ferromagnetic resonance frequency to change within the range of 2.6 to 4.2 GHz.

### Implementation Example

Next, an implementation example of the magnetoresistance effect device 1 according to the present embodiment will be described. To begin with, a description will be given of the configuration of the magnetoresistance effect element 2 in the implementation example. In the implementation example, the magnetoresistance effect element 2 includes a first ferromagnetic layer 21, a second ferromagnetic layer 23, a spacer layer 22, an antiferromagnetic layer, a first metal layer, and a second metal layer. The first ferromagnetic layer 21 is formed of a 2-nm thick CoFeB layer. The second ferromagnetic layer 23 is formed of a 50-nm thick CoFe layer. The spacer layer 22 is formed of a 1-nm thick MgO layer. The antiferromagnetic layer is formed of a 100-nm thick IrMn layer. The first and second metal layers are each formed of an Ru layer. The magnetoresistance effect element 2 is 150 nm in dimension in each of the X direction and the Y direction.

Next, the configuration of the external magnetic field application unit 3 in the implementation example will be described. In the implementation example, the yoke 31 of the magnetization setting section 30 is formed of NiFe. The yoke 31 is 1 μm thick in the Z direction. Frame plating was employed to form the yoke 31. The coil 32 of the magnetization setting section 30 is formed of Cu. The coil 32 is 0.5 μm thick in a direction perpendicular to the outer surface of the yoke 31. An insulating film of SiO₂ is interposed between the yoke 31 and the coil 32. The minimum value of the distance between the yoke 31 and the coil 32 is 0.1 μm.

Each of the first and second portions 35A and 35B of the magnetization retention section 35 is formed of an alloy predominantly composed of Co with V and Cr added thereto. The first and second portions 35A and 35B are each 0.5 μm in dimension in the X direction, 0.2 μm in dimension in the Y direction, and 0.2 μm in thickness in the Z direction. Each of the first and second portions 35A and 35B has a shape magnetic anisotropy in a direction parallel to the X direction. Each of the first and second portions 35A and 35B has a residual magnetization of 12 kG. Each of the first and second portions 35A and 35B has a coercivity of 200 Oe. Each of the first and second portions 35A and 35B has a squareness ratio of 0.8.

An insulating film of SiO₂ is interposed between each of the first and second portions 35A and 35B and the magnetoresistance effect element 2, and between each of the first and second portions 35A and 35B and the yoke 31. The minimum value of the distance between each of the first and second portions 35A and 35B and the magnetoresistance effect element 2 is 10 nm. The minimum value of the distance between each of the first and second portions 35A and 35B and the yoke 31 is 0.1 μm.

Next, the configuration of other parts of the magnetoresistance effect device 1 in the implementation example will be described. The first electrode 11 is formed of a layered film constituted of a 100-nm thick Cu layer and a 100-nm thick Au layer. The second electrode 12 is formed of a 100-nm thick Cu layer. The first and second signal lines 6 and 7 are each formed of Cu. The signal lines 6 and 7 and the ground electrode 13 are formed of coplanar waveguides. Each of the first and second signal lines 6 and 7 has a line width of 50 μm. Each of the first and second signal lines 6 and 7 has a thickness of 100 nm or more. The choke coil 14 has an inductance of 100 nH. The maximum value of the current generated by the direct current source is 10 mA.

In the external magnetic field application unit 3 of the implementation example, when a coil current of 10 mA is supplied to the coil 32 by the direct current source 36, a magnetization-setting magnetic field of 1000 Oe is generated from the yoke 31. In the implementation example, if, in accordance with the first example of the method for setting the third-magnetization, the magnetization-setting magnetic field of 1000 Oe is applied to each of the first and second portions 35A and 35B and then the application of the magnetization-setting magnetic field is stopped, the third magnetization set into each of the first and second portions 35A and 35B generates an external magnetic field having a magnitude of 800 Oe. In this case, according to the example shown in FIG. 11, the ferromagnetic resonance frequency of the first ferromagnetic layer 21 is 4.2 GHz.

Further, in the implementation example, if, in accordance with the second or third example of the method for setting the third-magnetization, a magnetization-setting magnetic field of 750 Oe is applied to each of the first and second portions 35A and 35B and then the application of the magnetization-setting magnetic field is stopped, the third magnetization set into each of the first and second portions 35A and 35B generates an external magnetic field having a magnitude of 600 Oe. In this case, according to the example shown in FIG. 11, the ferromagnetic resonance frequency of the first ferromagnetic layer 21 is 3.5 GHz.

The foregoing example being non-limiting, in the implementation example the magnitude of the external magnetic field and the ferromagnetic resonance frequency of the first ferromagnetic layer 21 can be changed by changing the magnitude of the magnetization-setting magnetic field applied to each of the first and second portions 35A and 35B in accordance with the second or third example of the method for setting the third magnetization.

### Second Embodiment

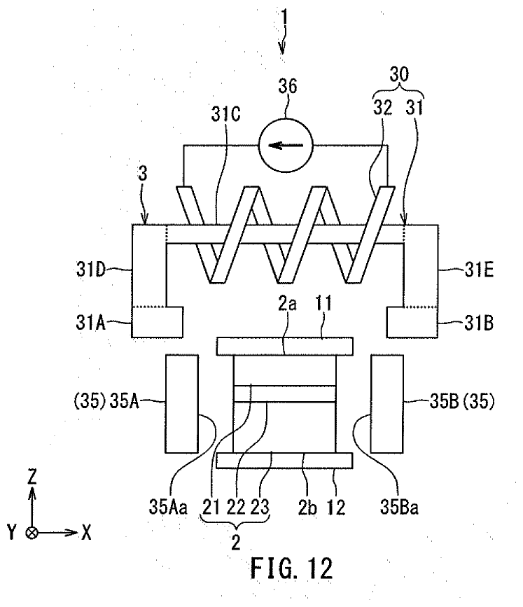

Next, a second embodiment of the present invention will be described. To begin with, the configuration of a magnetoresistance effect device 1 according to the present embodiment will be described with reference to FIG. 12. FIG. 12 is an explanatory diagram schematically showing the magnetoresistance effect device 1 according to the present embodiment. The configuration of the magnetoresistance effect device 1 according to the present embodiment differs from the first embodiment in the following ways. In the present embodiment, the first portion 35A of the magnetization retention section 35, the magnetoresistance effect element 2, and the second portion 35B of the magnetization retention section 35 are arranged in this order in a row along the X direction. However, the first pole section 31A and the second pole section 31B of the yoke 31 are located at positions offset with respect to the row of the first portion 35A, the magnetoresistance effect element 2 and the second portion 35B in a direction orthogonal to the X direction. FIG. 12 shows an example in which the first and second pole sections 31A and 31B are located at positions offset in the Z direction with respect to the row of the first portion 35A, the magnetoresistance effect element 2 and the second portion 35B. However, the first and second pole sections 31A and 31B may be located at positions offset in the Y direction with respect to the row of the first portion 35A, the magnetoresistance effect element 2 and the second portion 35B.

The first pole section 31A is located near the first portion 35A. The first pole section 31A may be in contact with the first portion 35A or be adjacent to the first portion 35A with a non-illustrated nonmagnetic film interposed therebetween. Similarly, the second pole section 31B is located near the second portion 35B. The second pole section 31B may be in contact with the second portion 35B or be adjacent to the second portion 35B with a non-illustrated nonmagnetic film interposed therebetween. The distance between the first pole section 31A and the first portion 35A and the distance between the second pole section 31B and the second portion 35B are preferably 10 μm or less.

The present embodiment enables reduction in size of the yoke 31 as compared with the first embodiment, and consequently enables miniaturization of the magnetoresistance effect device 1. This makes it possible to reduce the first and second signal lines 6 and 7 in length to thereby reduce losses of the high frequency input signal and the high frequency output signal.

The remainder of configuration, operation and effects of the present embodiment are similar to those of the first embodiment.

### Third Embodiment

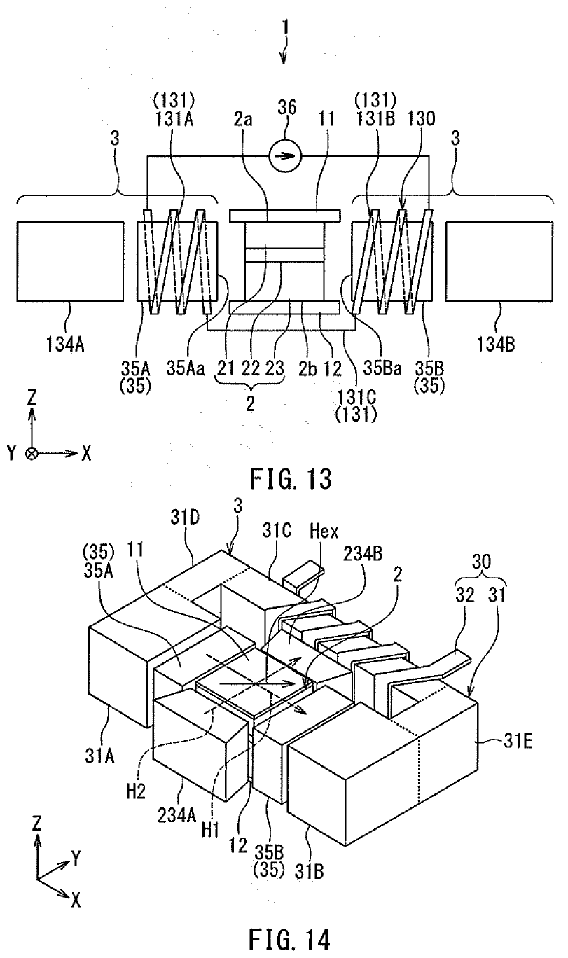

Next, a third embodiment of the present invention will be described. To begin with, the configuration of a magnetoresistance effect device 1 according to the present embodiment will be described with reference to FIG. 13. FIG. 13 is an explanatory diagram schematically showing the magnetoresistance effect device 1 according to the present embodiment. The configuration of the magnetoresistance effect device 1 according to the present embodiment differs from the first embodiment in the following ways. In the present embodiment, the external magnetic field application unit 3 includes a magnetization setting section 130 in place of the magnetization setting section 30 of the first embodiment. The magnetization setting section 130 has the same function as the magnetization setting section 30. Specifically, the magnetization setting section 130 has the function of setting the third magnetization to be used to generate the external magnetic field into the magnetization retention section 35 by applying a magnetization-setting magnetic field to the magnetization retention section 35 and then stopping the application of the magnetization-setting magnetic field. As in the first embodiment, the magnetization retention section 35 includes the first portion 35A and the second portion 35B.

The magnetization setting section 130 has a conductive line 131. The conductive line 131 includes a first winding portion 131A, a second winding portion 131B, and a connecting portion 131C connecting the first winding portion 131A and the second winding portion 131B. The magnetization setting section 130 has no yoke.

The first winding portion 131A is wound around the first portion 35A of the magnetization retention section 35. The second winding portion 131B is wound around the second portion 35B of the magnetization retention section 35. The conductive line 131 is formed of a conductive material similar to that used for the coil 32 of the first embodiment. A non-illustrated insulating film is interposed between the first winding portion 131A and the first portion 35A, and between the second winding portion 131B and the second portion 35B.

The external magnetic field application unit 3 further includes a first permanent magnet 134A and a second permanent magnet 131B. As shown in FIG. 13, the first permanent magnet 134A and the second permanent magnet 131B are disposed such that the first portion 35A, the magnetoresistance effect element 2 and the second portion 35B are interposed between them. Specifically, the first permanent magnet 134A, the first portion 35A, the magnetoresistance effect element 2, the second portion 35B, and the second permanent magnet 134A are arranged in this order in a row along the X direction.

Next, the operation and effects of the magnetoresistance effect device 1 according to the present embodiment will be described. To apply a magnetization-setting magnetic field to the magnetization retention section 35, the direct current source 36 is connected to the conductive line 131, as shown in FIG. 13. By passing a current through the conductive line 131 using the direct current source 36, a magnetization-setting magnetic field occurs from the first and second winding portions 131A and 131B, so that the third magnetization is set into each of the first and the second portions 35A and 35B based on this magnetization-setting magnetic field. The third magnetization set into each of the first and second portions 35A and 35B generates a first magnetic field.

The first and second permanent magnets 134A and 134B generate a second magnetic field having a fixed direction and a fixed magnitude. The first magnetic field and direction and the direction of the second magnetic field are both parallel to the X direction. In the present embodiment, the external magnetic field applied to the magnetoresistance effect element 2 is a composite of the first magnetic field and the second magnetic field. According to the present embodiment, the ferromagnetic resonance frequency of the first ferromagnetic layer 21 can be set to a predetermined frequency by using the external magnetic field that is a composite of the first magnetic field and the second magnetic field, and further, the ferromagnetic resonance frequency can be changed by changing the first magnetic field in magnitude only or in both of magnitude and direction.

For example, if the magnitude of the external magnetic field and the ferromagnetic resonance frequency have the relationship shown in FIG. 11, the magnitude of the second magnetic field is set to 600 Oe and the magnitude and direction of the first magnetic field are changed within the range of −200 to 200 Oe. This makes it possible to change the magnitude of the external magnetic field over the range of 400 to 800 Oe to thereby change the ferromagnetic resonance frequency within the range of 2.6 to 4.2 GHz.

According to the present embodiment, the first magnetic field generated by the third magnetization can be made smaller in maximum absolute value than in the case where the first and second permanent magnets 134A and 134B are not provided. The present embodiment thus enables reduction in the power required for generating the first magnetic field, as compared to the first and second embodiments. By virtue of this, the present embodiment enables reduction in size of the first and second portions 35A and 35B of the magnetization retention section 35. Further, the present embodiment enables reduction in maximum absolute value of the magnetization-setting magnetic field. The present embodiment thereby makes it possible to simplify the structure of the external magnetic field application unit 3 and miniaturize the external magnetic field application unit 3, and consequently makes it possible to miniaturize the magnetoresistance effect device 1.

The remainder of configuration, operation and effects of the present embodiment are similar to those of the first embodiment.

### Fourth Embodiment

Next, a fourth embodiment of the present invention will be described. To begin with, the configuration of a magnetoresistance effect device 1 according to the present embodiment will be described with reference to FIG. 14. FIG. 14 is a perspective view showing the main part of the magnetoresistance effect device 1 according to the present embodiment. The configuration of the magnetoresistance effect device 1 according to the present embodiment differs from the first embodiment in the following ways. In the present embodiment, the external magnetic field application unit 3 includes a first permanent magnet 234A and a second permanent magnet 234B in addition to the magnetization retention section 35 and the magnetization setting section 30 described in relation to the first embodiment. As shown in FIG. 14, the first permanent magnet 234A and the second permanent magnet 234B are disposed on opposite sides of the magnetoresistance effect element 2 in the Y direction.

Next, the operation and effects of the magnetoresistance effect device 1 according to the present embodiment will be described. As shown in FIG. 14, the third magnetization set into each of the first and second portions 35A and 35B generates a first magnetic field H1. On the other hand, the first and second permanent magnets 234A and 234B generate a second magnetic field H2 having a fixed direction and a fixed magnitude. The direction of the first magnetic field H1 is parallel to the X direction. The direction of the second magnetic field H2 is parallel to the Y direction.

In the present embodiment, the external magnetic field Hex applied to the magnetoresistance effect element 2 is a composite of the first magnetic field H1 and the second magnetic field H2. If the magnitude of the first magnetic field H1 is 0, the direction and magnitude of the external magnetic field Hex coincide with the direction and magnitude of the second magnetic field H2. If the magnitude of the first magnetic field H1 is other than 0, the direction of the external magnetic field Hex tilts with respect to the X direction and the Y direction.

The direction and magnitude of the external magnetic field Hex change with the magnitude of the first magnetic field H1. The magnitude of the first magnetic field H1 changes with the magnitude of the third magnetization. Thus, in the present embodiment the direction and magnitude of the external magnetic field Hex change with the magnitude of the third magnetization.

The direction of the external magnetic field Hex changes also with the direction of the first magnetic field H1. The direction of the first magnetic field H1 coincides with the direction of the third magnetization. Thus, in the present embodiment the direction of the external magnetic field Hex changes also with the direction of the third magnetization.

Here, let θ represent the angle that the direction of the external magnetic field Hex form with respect to the direction of the second magnetic field H2. In the case of changing only the magnitude of the first magnetic field H1, θ can be changed within the range from 0° to less than 90°. In the case of changing the magnitude and direction of the first magnetic field H1, θ can be changed within the range greater than −90° and less than 90°.

The remainder of configuration, operation and effects of the present embodiment are similar to those of the first embodiment.

### Fifth Embodiment

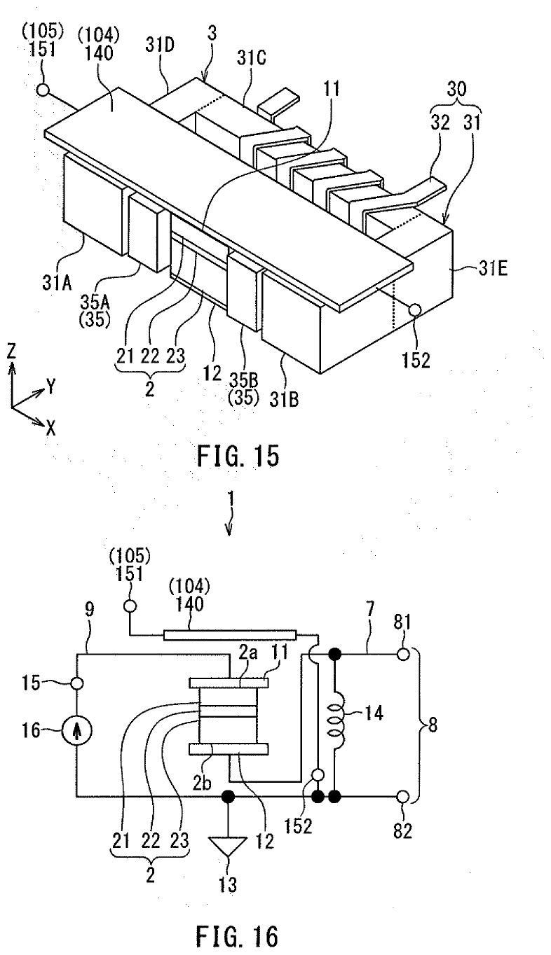

Next, a fifth embodiment of the present invention will be described. To begin with, the configuration of a magnetoresistance effect device 1 according to the present embodiment will be described with reference to FIG. 15 and FIG. 16. FIG. 15 is a perspective view showing the main part of the magnetoresistance effect device 1 according to the present embodiment. FIG. 16 is a circuit diagram showing the circuit configuration of the magnetoresistance effect device 1 according to the present embodiment.

The configuration of the magnetoresistance effect device 1 according to the present embodiment differs from the first embodiment in the following ways. The magnetoresistance effect device 1 according to the present embodiment includes an energy application unit 104 in place of the energy application unit 4 of the first embodiment. The energy application unit 104 applies energy for oscillating the first magnetization of the first ferromagnetic layer 21 to the magnetoresistance effect element 2. In the present embodiment, specifically, a high frequency magnetic field is used as the energy for oscillating the first magnetization. The energy application unit 104 is configured to be able to apply a high frequency magnetic field as the energy to the magnetoresistance effect element 2. Specifically, the energy application unit 104 includes a high frequency magnetic field generation section 140, and an input port 105 for receiving a high frequency input signal. The high frequency magnetic field generation section 140 transmits a high frequency current based on the high frequency input signal, and generates a high frequency magnetic field based on the high frequency current. This high frequency magnetic field is applied to the magnetoresistance effect element 2. The magnitude of the high frequency magnetic field is lower than the coercivity of the magnetic material 35M forming the magnetization retention section 35. The frequency of the high frequency current is equal to the frequency of the high frequency input signal.

In the example shown in FIG. 15, the high frequency magnetic field generation section 140 is a line extending in the X direction, and is disposed above the first electrode 11, the first and second pole sections 31A and 31B of the yoke 31 of the magnetization setting section 30 and the first and second portions 35A and 35B of the magnetization retention section 35. The high frequency magnetic field generation section 140 is formed of a conductive material similar to that used for the coil 32 of the magnetization setting section 30. A non-illustrated insulating film is interposed between the high frequency magnetic field generation section 140 and the first electrode 11.

In the example shown in FIG. 15 and FIG. 16, the input port 105 has a terminal 151. The terminal 151 is electrically connected to one end of the high frequency magnetic field generation section 140. The other end of the high frequency magnetic field generation section 140 is electrically connected to the ground electrode 13 via a terminal 152.

Further, as shown in FIG. 16, the magnetoresistance effect device 1 according to the present embodiment includes a direct current line 9. One end of the direct current line 9 is electrically connected to the first electrode 11. The other end of the direct current line 9 is electrically connected to the direct current input terminal 15. The second signal line 7, the direct current line 9 and the ground electrode 13 may be formed of microstrip lines or coplanar waveguides.

To effect the operation of the magnetoresistance effect device 1, as shown in FIG. 16, the direct current source 16 is provided between the direct current input terminal 15 and the ground electrode 13. As a result, there is formed a closed circuit including the direct current source 16, the direct current input terminal 15, the direct current line 9, the magnetoresistance effect element 2, the second signal line 7, the choke coil 14 and the ground electrode 13.

Next, the operation and effects of the magnetoresistance effect device 1 according to the present embodiment will be described. In the present embodiment, applied to the first ferromagnetic layer 21 is a composite magnetic field of an external magnetic field generated by the third magnetization set into each of the first and second portions 35A and 35B of the magnetization retention section 35 and a high frequency magnetic field generated by the high frequency magnetic field generation section 140. Hereinafter, the composite magnetic field of the external magnetic field and the high frequency magnetic field will be referred to as a high frequency superposition magnetic field. In the present embodiment, the direction of the effective magnetic field acting on the first magnetization of the first ferromagnetic layer 21 coincides or substantially coincides with the direction of the high frequency superposition magnetic field.

The high frequency magnetic field causes the direction of the high frequency superposition magnetic field to change in such a manner as to oscillate around the direction of the external magnetic field. In the present embodiment, the direction of the high frequency magnetic field is parallel to the Y direction. The high frequency magnetic field thus changes the direction of the high frequency superposition magnetic field into a direction tilted toward the Y direction or −Y direction from the direction of the external magnetic field. The frequency of change of the direction of the high frequency superposition magnetic field is equal to the frequency of the high frequency current. As the direction of the high frequency superposition magnetic field changes, damping torque acting on the first magnetization of the first ferromagnetic layer 21 changes. This causes the first magnetization to oscillate at the frequency of the high frequency current so that its direction changes.

The magnetoresistance effect element 2 generates a high frequency output signal resulting from the oscillation of the first magnetization. The high frequency output signal has a frequency equal to that of the high frequency input signal. The high frequency output signal is transmitted from the magnetoresistance effect element 2 to the output port 8 by the second signal line 7. This high frequency output signal comes out from the output port 8.

If the frequency of the high frequency input signal is equal to the ferromagnetic resonance frequency of the first ferromagnetic layer 21, ferromagnetic resonance occurs in the first ferromagnetic layer 21 to maximize the amplitude of the oscillation of the first magnetization. As a result, the amplitude of the high frequency output signal also becomes maximum.

The remainder of configuration, operation and effects of the present embodiment are similar to those of the first embodiment.

### Sixth Embodiment

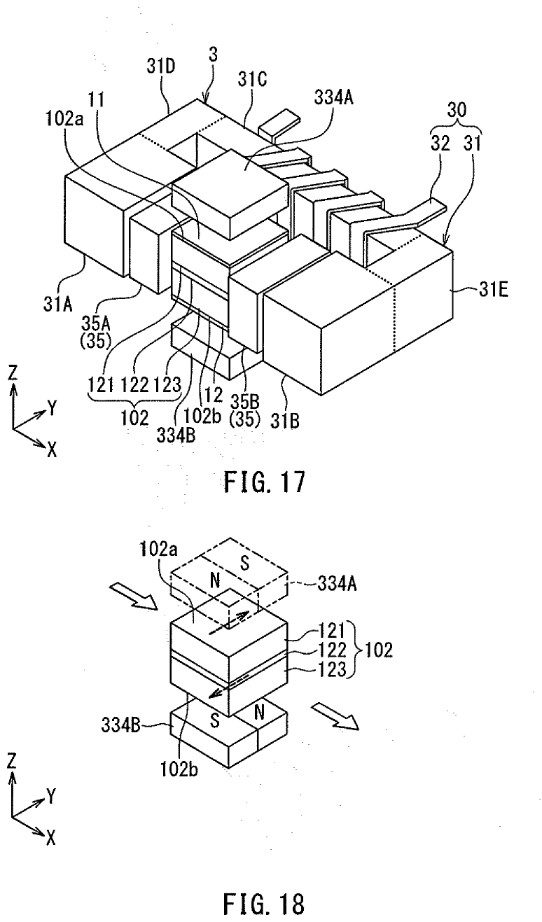

Next, a sixth embodiment of the present invention will be described. To begin with, the configuration of a magnetoresistance effect device 1 according to the present embodiment will be described with reference to FIG. 17. FIG. 17 is a perspective view showing the main part of the magnetoresistance effect device 1 according to the present embodiment. The configuration of the magnetoresistance effect device 1 according to the present embodiment differs from the first embodiment in the following ways. The magnetoresistance effect device 1 according to the present embodiment includes a magnetoresistance effect element 102 in place of the magnetoresistance effect element 2 of the first embodiment.

The magnetoresistance effect element 102 includes a first ferromagnetic layer 121 and a second ferromagnetic layer 123 each formed of a ferromagnetic material, and a spacer layer 122 disposed between the first ferromagnetic layer 121 and the second ferromagnetic layer 123. The first ferromagnetic layer 121 has a first magnetization, and the second ferromagnetic layer 123 has a second magnetization. In the magnetoresistance effect element 102, the first magnetization and the second magnetization interact with each other to produce a magnetoresistance effect.

In the present embodiment, specifically, both the first ferromagnetic layer 121 and the second ferromagnetic layer 123 are magnetization free layers. The first magnetization changes in direction depending on an effective magnetic field acting on the first magnetization (hereinafter referred to as a first effective magnetic field). The second magnetization changes in direction depending on an effective magnetic field acting on the second magnetization (hereinafter referred to as a second effective magnetic field).

The magnetoresistance effect element 102 has a first end face 102a and a second end face 102b lying at opposite ends in the stacking direction of the layers constituting the magnetoresistance effect element 102. FIG. 17 shows an example in which the second ferromagnetic layer 123, the spacer layer 122, and the first ferromagnetic layer 121 are stacked in this order, from closest to farthest from the second end face 102b. In the present embodiment, the first electrode 11 is in contact with the first end face 102a. The second electrode 12 is in contact with the second end face 102b. The first electrode 11 and the second electrode 12 are used to feed a direct current through the magnetoresistance effect element 2.

As shown in FIG. 17, in the present embodiment the Z direction is defined as the direction perpendicular to the interface between the second ferromagnetic layer 123 and the spacer layer 122 and toward the first ferromagnetic layer 121 from the second ferromagnetic layer 123. The X direction and the Y direction are as described in relation to the first embodiment.

In the present embodiment, the external magnetic field application unit 3 includes a first permanent magnet 334A and a second permanent magnet 334B in addition to the magnetization retention section 35 and the magnetization setting section 30 described in relation to the first embodiment. As shown in FIG. 17, the first permanent magnet 334A and the second permanent magnet 334B are disposed on opposite sides of the magnetoresistance effect element 102 in the Z direction. The first permanent magnet 334A is disposed near the first ferromagnetic layer 121. The second permanent magnet 334B is disposed near the second ferromagnetic layer 123.

The positional relationship between the magnetoresistance effect element 102 and each of the magnetization retention section 35 and the magnetization setting section 30 is the same as that between the magnetoresistance effect element 2 and each of the magnetization retention section 35 and the magnetization setting section 30 in the first embodiment.

Although not illustrated, the magnetoresistance effect device 1 according to the present embodiment includes the energy application unit 4, the second signal line 7, the output port 8, the ground electrode 13, the choke coil 14 and the direct current input terminal 15 of the first embodiment shown in FIG. 1. In the present embodiment, the energy application unit 4 applies energy for oscillating the first magnetization and the second magnetization to the magnetoresistance effect element 102. In the present embodiment, specifically, a high frequency current is used as the energy for oscillating the first magnetization and the second magnetization. The energy application unit 4 is configured to be able to apply a high frequency current as the energy to the magnetoresistance effect element 102. The specific configuration of the energy application unit 4 is the same as that in the first embodiment.

The first and second ferromagnetic layers 121 and 123 of the magnetoresistance effect element 2 are formed of ferromagnetic material. Specific examples of the ferromagnetic material forming the first and second ferromagnetic layers 121 and 123 and the preferable range of thickness of each of the first and second ferromagnetic layers 121 and 123 are the same as those for the first ferromagnetic layer 21 of the first embodiment where the direction of the easy axis of magnetization of the first ferromagnetic layer 21 is parallel to the interface between the first ferromagnetic layer 21 and the spacer layer 22.

The spacer layer 122 of the magnetoresistance effect element 2 is formed of a similar material to that used for the spacer layer 22 of the first embodiment.

Next, with reference to FIG. 17 and FIG. 18, a description will be given of a magnetic field applied to the first and second ferromagnetic layers 121 and 123. FIG. 18 is an explanatory diagram for describing the magnetic field applied to the first and second ferromagnetic layers 121 and 123. Applied to the first ferromagnetic layer 121 is a composite magnetic field (hereinafter referred to as a first external magnetic field) of a first magnetic field generated by the third magnetization set into each of the first and second portions 35A and 35B of the magnetization retention section 35 and a magnetic field generated by the first permanent magnet 334A. The magnetic field generated by the first permanent magnet 334A corresponds to the second magnetic field in the present invention. In the present embodiment, the direction of the first effective magnetic field coincides or substantially coincides with the direction of the first external magnetic field.

Applied to the second ferromagnetic layer 123 is a composite magnetic field (hereinafter referred to as a second external magnetic field) of the foregoing first magnetic field and a magnetic field generated by the second permanent magnet 334B. The magnetic field generated by the second permanent magnet 334B corresponds to the second magnetic field in the present invention. In the present embodiment, the direction of the second effective magnetic field coincides or substantially coincides with the direction of the second external magnetic field.

As shown in FIG. 18, in the first permanent magnet 334A the N pole and the S pole are arranged in this order in the Y direction. In FIG. 18 the arrow drawn in the first ferromagnetic layer 121 represents the magnetic field generated by the first permanent magnet 334A and applied to the first ferromagnetic layer 121. This magnetic field is in the Y direction.

Further, as shown in FIG. 18, in the second permanent magnet 334B the S pole and the N pole are arranged in this order in the Y direction. In FIG. 18 the arrow drawn in the second ferromagnetic layer 123 represents the magnetic field generated by the second permanent magnet 3348 and applied to the second ferromagnetic layer 123. This magnetic field is in the −Y direction.

The hollow arrows in FIG. 18 represent an example of the direction of the first magnetic field. FIG. 18 shows an example in which the first magnetic field is in the X direction. In this case, the direction of the first external magnetic field tilts by a predetermined angle toward the X direction from the Y direction, and the direction of the second external magnetic field tilts by a predetermined angle toward the X direction from the −Y direction.

If the magnetic field generated by the third magnetization is 0 in value, the direction of the first external magnetic field is the Y direction, and the direction of the second external magnetic field is the −Y direction. If the magnetic field generated by the third magnetization is in the −X direction, the direction of the first external magnetic field tilts by a predetermined angle toward the −X direction from the Y direction, and the direction of the second external magnetic field tilts by a predetermined angle toward the −X direction from the −Y direction.

The direction and magnitude of each of the first and second external magnetic fields change with the magnitude of the first magnetic field. The magnitude of the first magnetic field changes with the magnitude of the third magnetization. Thus, in the present embodiment the direction and magnitude of each of the first and second external magnetic fields change with the magnitude of the third magnetization.

The direction of each of the first and second external magnetic fields changes also with the direction of the first magnetic field. The direction of the first magnetic field coincides with the direction of the third magnetization. Thus, in the present embodiment the direction of each of the first and second external magnetic fields changes also with the direction of the third magnetization.

Next, the operation and effects of the magnetoresistance effect device 1 according to the present embodiment will be described. To begin with, a description will be given of the behavior of the first magnetization of the first ferromagnetic layer 121 and the second magnetization of the second ferromagnetic layer 123. The first effective magnetic field acts on the first magnetization, and the second effective magnetic field acts on the second magnetization.

In the present embodiment, energy for causing the first and second magnetizations to make oscillations based on a high frequency current is applied by the energy application unit 4 to the magnetoresistance effect element 102. In the present embodiment, the foregoing energy is a high frequency current. The high frequency current is superposed on the direct current flowing through the magnetoresistance effect element 102 and applied to the magnetoresistance effect element 102. Once the high frequency current has been applied to the magnetoresistance effect element 102, the current density in the first ferromagnetic layer 121 and the current density in the second ferromagnetic layer 123 change at the frequency of the high frequency current. As a result, the STTs respectively acting on the first and second magnetizations change at the frequency of the high frequency current. This causes the first and second magnetizations to oscillate at the frequency of the high frequency current so that their directions change.

In the magnetoresistance effect device 1 according to the present embodiment, the ferromagnetic resonance frequency of the first ferromagnetic layer 121 and the ferromagnetic resonance frequency of the second ferromagnetic layer 123 are made different from each other. This will be described in detail below. The first ferromagnetic layer 121 has a first ferromagnetic resonance frequency, and the second ferromagnetic layer 123 has a second ferromagnetic resonance frequency. The first and second ferromagnetic resonance frequencies change with the magnitudes of the first and second effective magnetic fields, respectively. In the present embodiment, the magnitude of the magnetic field generated by the first permanent magnet 334A and the magnitude of the magnetic field generated by the second permanent magnet 334B are made different from each other to cause the first and second effective magnetic fields to differ in magnitude from each other, whereby the first and second ferromagnetic resonance frequencies are made different from each other.

If the frequency of the high frequency input signal is equal to the first ferromagnetic resonance frequency, ferromagnetic resonance occurs in the first ferromagnetic layer 121 to maximize the amplitude of the oscillation of the first magnetization. If the frequency of the high frequency input signal is equal to the second ferromagnetic resonance frequency, ferromagnetic resonance occurs in the second ferromagnetic layer 123 to maximize the amplitude of the oscillation of the second magnetization.

In the present embodiment, the high frequency output signal results from the oscillation of the first magnetization and the oscillation of the second magnetization. The resistance value of the magnetoresistance effect element 102 changes with the relative angle between the direction of the first magnetization and the direction of the second magnetization. The high frequency output signal is generated by the change in the resistance value of the magnetoresistance effect element 102.

The magnetoresistance effect device 1 according to the present embodiment can be operated as a band-pass filter. Here, the ratio of the power of the high frequency output signal to the power of the high frequency input signal will be referred to as input-to-output power ratio. The input-to-output power ratio has a frequency response that takes on maximal values at both the first ferromagnetic resonance frequency and the second ferromagnetic resonance frequency. A frequency band where the input-to-output power ratio is higher than or equal to a predetermined value corresponds to the passband of the band-pass filter. For example, the predetermined value is ½ the maximum value of the input-to-output power ratio. Since the frequency response of the input-to-output power ratio takes on maximal values at two frequencies, the magnetoresistance effect device 1 according to the present embodiment is able to widen a predetermined frequency band corresponding to the passband of the bandpass filter, compared to when the frequency response of the input-to-output power ratio takes on a maximal value at a single frequency. Thus, by making the first and second ferromagnetic resonance frequencies different from each other, it is possible for the magnetoresistance effect device 1 according to the present embodiment to achieve a wider passband when operated as a band-pass filter.

The remainder of configuration, operation and effects of the present embodiment are similar to those of the first embodiment.

### Seventh Embodiment

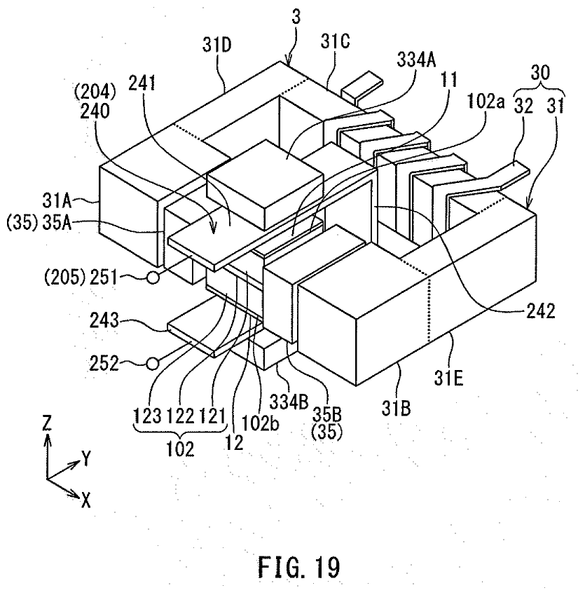

Next, a seventh embodiment of the present invention will be described. To begin with, the configuration of a magnetoresistance effect device 1 according to the present embodiment will be described with reference to FIG. 19. The configuration of the magnetoresistance effect device 1 according to the present embodiment differs from the sixth embodiment in the following ways. The magnetoresistance effect device 1 according to the present embodiment includes an energy application unit 204 in place of the energy application unit 4 of the sixth embodiment. The energy application unit 204 applies energy for oscillating the first magnetization of the first ferromagnetic layer 121 and the second magnetization of the second ferromagnetic layer 123 to the magnetoresistance effect element 102. In the present embodiment, specifically, a high frequency magnetic field is used as the energy for oscillating the first magnetization and the second magnetization. The energy application unit 204 is configured to be able to apply a high frequency magnetic field as the energy to the magnetoresistance effect element 102. Specifically, the energy application unit 204 includes a high frequency magnetic field generation section 240, and an input port 205 for receiving a high frequency input signal. The high frequency magnetic field generation section 240 transmits a high frequency current based on the high frequency input signal, and generates a high frequency magnetic field based on the high frequency current. This high frequency magnetic field is applied to the magnetoresistance effect element 102. The magnitude of the high frequency magnetic field is lower than the coercivity of the magnetic material 35M forming the magnetization retention section 35. The frequency of the high frequency current is equal to the frequency of the high frequency input signal.

The high frequency magnetic field generation section 240 includes line portions 241, 242, and 243. The line portions 241, 242, and 243 are connected in series in this order. As shown in FIG. 19, the line portion 241 extends in the Y direction to pass between the first electrode 11 and the first permanent magnet 334A. The line portion 243 extends in the Y direction to pass between the second electrode 12 and the second permanent magnet 334B. The line portions 241, 242, and 243 are formed of a conductive material similar to that used for the coil 32 of the magnetization setting section 30. A non-illustrated insulating film is interposed between the line portion 241 and the first electrode 11, between the line portion 241 and the first permanent magnet 334A, between the line portion 243 and the second electrode 12, and between the line portion 243 and the second permanent magnet 334B.

In the example shown in FIG. 19, the input port 205 has a terminal 251. The terminal 251 is electrically connected to an end of the line portion 241 farther from the connection point between the line portions 241 and 242. An end of the line portion 243 farther from the connection point between the line portions 242 and 243 is electrically connected to the ground electrode 13 via a terminal 252 in a manner similar to that in which the other end of the high frequency magnetic field generation section 140 in FIG. 16 is electrically connected to the ground electrode 13 via the terminal 152.

Next, the operation and effects of the magnetoresistance effect device 1 according to the present embodiment will be described. In the present embodiment, applied to the first ferromagnetic layer 121 is a composite magnetic field of the high frequency magnetic field and the first external magnetic field described in relation to the sixth embodiment. Applied to the second ferromagnetic layer 123 is a composite magnetic field of the high frequency magnetic field and the second external magnetic field described in relation to the sixth embodiment. Hereinafter, the composite magnetic field of the high frequency magnetic field and the first external magnetic field will be referred to as a first high frequency superposition magnetic field, and the composite magnetic field of the high frequency magnetic field and the second external magnetic field will be referred to as a second high frequency superposition magnetic field. In the present embodiment, the direction of the first effective magnetic field acting on the first magnetization of the first ferromagnetic layer 121 coincides or substantially coincides with the direction of the first high frequency superposition magnetic field. The direction of the second effective magnetic field acting on the second magnetization of the second ferromagnetic layer 123 coincides or substantially coincides with the direction of the second high frequency superposition magnetic field.

The high frequency magnetic field causes the direction of the first high frequency superposition magnetic field to change in such a manner as to oscillate around the direction of the first external magnetic field. The frequency of change of the direction of the first high frequency superposition magnetic field is equal to the frequency of the high frequency current. As the direction of the first high frequency superposition magnetic field changes, damping torque acting on the first magnetization of the first ferromagnetic layer 121 changes. This causes the first magnetization to oscillate at the frequency of the high frequency current so that its direction changes.

Further, the high frequency magnetic field causes the direction of the second high frequency superposition magnetic field to change in such a manner as to oscillate around the direction of the second external magnetic field. The frequency of change of the direction of the second high frequency superposition magnetic field is equal to the frequency of the high frequency current. As the direction of the second high frequency superposition magnetic field changes, damping torque acting on the second magnetization of the second ferromagnetic layer 123 changes. This causes the second magnetization to oscillate at the frequency of the high frequency current so that its direction changes.

In the present embodiment, once the high frequency magnetic field has been applied to the magnetoresistance effect element 102, the first and second magnetizations oscillate such that their directions change to mutually opposite directions. The relative angle between the direction of the first magnetization and the direction of the second magnetization thereby changes to cause a change in the resistance value of the magnetoresistance effect element 102. As a result, a high frequency output signal having a frequency equal to that of the high frequency input signal is generated.

In the present embodiment, the first ferromagnetic resonance frequency of the first ferromagnetic layer 121 and the second ferromagnetic resonance frequency of the second ferromagnetic layer 123 may be equal or different. If the first ferromagnetic resonance frequency and the second ferromagnetic resonance frequency are equal, it is possible to make the maximum value of the amplitude of the high frequency output signal greater than in the fifth embodiment.

The remainder of configuration, operation and effects of the present embodiment are similar to those of the sixth embodiment.

The present invention is not limited to the foregoing embodiments, but various modification can be made thereto. For example, as long as the requirements of the claims are met, the configuration of the external magnetic field application unit 3 is not limited to the examples illustrated in the embodiments but can be freely chosen. For example, the magnetization retention section 35 may include only one of the first portion 35A and the second portion 35B.

Further, the first portion 35A and the second portion 35B may be disposed on opposite sides of the magnetoresistance effect element 2 in the Z direction, and the third magnetization set into each of the first and second portions 35A and 35B may be in a direction parallel to the Z direction, that is, in the direction in which the layers constituting the magnetoresistance effect element 2 are stacked. In such a case, the first portion 35A, the magnetoresistance effect element 2, and the second portion 35B may be arranged in the direction parallel to the Z direction. In this case, the direction of the external magnetic field to be generated by the third magnetization is parallel to the Z direction. Alternatively, the first portion 35A, the magnetoresistance effect element 2, and the second portion 35B may be arranged in a direction tilted with respect to the Z direction. In this case, the direction of the external magnetic field to be generated by the third magnetization becomes tilted with respect to the Z direction.

The present invention is applicable not only to magnetoresistance effect devices that use the ferromagnetic resonance phenomenon, but also to magnetoresistance effect devices that use the spin torque oscillation phenomenon, such as oscillators, and magnetoresistance effect devices that are configured to apply an external magnetic field to the magnetoresistance effect element for use.

1. A magnetoresistance effect device comprising a magnetoresistance effect element, and an external magnetic field application unit for applying an external magnetic field to the magnetoresistance effect element, wherein
the magnetoresistance effect element includes a first ferromagnetic layer having a first magnetization, a second ferromagnetic layer having a second magnetization, and a spacer layer disposed between the first ferromagnetic layer and the second ferromagnetic layer,
at least one of the first and second magnetizations changes in direction depending on an effective magnetic field acting thereon,
the external magnetic field application unit includes a magnetization retention section and a magnetization setting section,
the magnetization setting section has a function of setting a third magnetization to be used to generate the external magnetic field into the magnetization retention section by applying a magnetization-setting magnetic field to the magnetization retention section and then stopping the application of the magnetization-setting magnetic field, and
the magnetization retention section has a function of retaining the third magnetization after the application of the magnetization-setting magnetic field is stopped.

2. The magnetoresistance effect device according to claim 1, wherein the magnetization retention section is formed of a semi-hard magnetic material or a hard magnetic material.

3. The magnetoresistance effect device according to claim 2, wherein the semi-hard magnetic material has a coercivity within a range of 10 to 250 Oe.

4. The magnetoresistance effect device according to claim 2, wherein the semi-hard magnetic material or the hard magnetic material has a magnetic property such that a saturation magnetic field is higher than twice a coercivity.

5. The magnetoresistance effect device according to claim 1, wherein
the magnetization retention section has an end face facing the magnetoresistance effect element, and
the magnetoresistance effect element is disposed such that an entirety of the magnetoresistance effect element is contained in a space that is defined by shifting an imaginary plane corresponding to the end face in a direction parallel to a direction of the third magnetization.

6. The magnetoresistance effect device according to claim 1, wherein the magnetization setting section is capable of changing the third magnetization in magnitude.

7. The magnetoresistance effect device according to claim 6, wherein a magnitude of the external magnetic field changes with the magnitude of the third magnetization.

8. The magnetoresistance effect device according to claim 7, wherein a ferromagnetic resonance frequency of at least one of the first and second ferromagnetic layers changes with the magnitude of the external magnetic field.

9. The magnetoresistance effect device according to claim 6, wherein a direction of the external magnetic field changes with the magnitude of the third magnetization.

10. The magnetoresistance effect device according to claim 1, wherein the magnetization setting section includes a yoke, and a coil wound around at least part of the yoke.

11. The magnetoresistance effect device according to claim 1, wherein
the external magnetic field application unit further includes a permanent magnet, and the external magnetic field is a composite of a first magnetic field generated by the third magnetization and a second magnetic field generated by the permanent magnet.

12. The magnetoresistance effect device according to claim 1, further comprising an energy application unit for applying energy for oscillating at least one of the first and second magnetizations to the magnetoresistance effect element.

13. The magnetoresistance effect device according to claim 12, wherein the energy application unit applies a high frequency current as the energy to the magnetoresistance effect element.

14. The magnetoresistance effect device according to claim 12, wherein the energy application unit applies a high frequency magnetic field as the energy to the magnetoresistance effect element.

15. The magnetoresistance effect device according to claim 12, further comprising an output port from which a high frequency output signal resulting from oscillation of the at least one of the first and second magnetizations comes out.
